(19) United States
(12) Patent Application Publication
(10) Pub. No.: US 2006/0071253 A1
(43) Pub. Date: Apr. 6, 2006

(54) Photoelectric conversion device and imaging device

(75) Inventor: Kazumi Nii, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/236,655

(22) Filed: Sep. 28, 2005

(30) Foreign Application Priority Data
Sep. 29, 2004 (JP) P.2004-283708

(51) Int. Cl. H01L 31/113

(52) U.S. Cl. 257/291

(57) ABSTRACT

A photoelectric conversion device comprises: at least two electrodes; and an organic photoelectric conversion film intervening between said at least two electrodes, the organic photoelectric conversion film comprising a positive hole transporting material containing an arylidene compound having a specific structure.

### BACKGROUND OF THE INVENTION

1. Field of the Invention

The present invention relates to such a photoelectric conversion film that has sharp spectral characteristics, a photoelectric conversion device having the photoelectric conversion film, a solid imaging device, and a method for applying an electric field to them.

2. Description of the Related Art

A photoelectric conversion film has been widely utilized, for example, as a light sensor, and in particular, it is preferably used as a solid imaging device (light receiving device) for an imaging apparatus (solid imaging apparatus), such as a television camera. As a material for a photoelectric conversion film used as a solid imaging device of an imaging apparatus, a film of an inorganic material, such as an Si film and an a-Si film, has been used.

The conventional photoelectric conversion film using the inorganic material has such a photoelectric conversion capability that has no steep wavelength dependency. Therefore, it is the mainstream that an imaging apparatus using the inorganic material as a photoelectric conversion film has a three-plate structure containing three photoelectric conversion films disposed behind a prism for dividing incident light into three primary colors, i.e., red, green and blue.

However, the imaging apparatus having the three-plate structure necessarily suffers increase in dimension and weight due to the structure thereof.

In order to reduce the size and weight of the imaging apparatus, one having a single plate structure having only one light receiving device without a spectral prism provided is demanded, and for example, an imaging apparatus having such a structure has been put into practical use and popularized that has red, green and blue filters are applied to a single plate light receiving device. However, the device has a complex structure due to the red, green and blue filters and microlenses or the like for improving the light condensing ratio, which are laminated in the device, and the device is inferior in utilization efficiency of light. As a measure using no filter, such a device is proposed that has photoelectric conversion films each having red, green and blue spectral characteristics, respectively, and a device using an organic material as the photoelectric conversion film is promising as a device capable of freely designing the light absorption characteristics.

Representative examples where an organic material is used as a photoelectric conversion film include electrophotography and a solar cell, and various materials therefor have been investigated. Examples of the material for electrophotography include the materials disclosed in Kock-Yee Law, Chem. Rev., vol. 93, p. 449 (1993), and the material for a solar cell include the material disclosed in S. R. Forrest, J. Appl. Phys., vol. 93, p. 3693 (2003). The materials disclosed in these literatures have a broad absorption spectrum as a film to provide a broad photoelectric conversion spectrum, which shows the wavelength dependency of the photoelectric conversion capability, and thus they fail to have such a sharp wavelength dependency that can provide spectral capability into red, green and blue colors. Furthermore, S. R. Forrest, J. Appl. Phys., vol. 93, p. 3693 (2003) discloses that BCP is introduced as an intermediate layer between the photoelectric conversion layer and the metallic electrode to improve the efficiency of the device. However, the device using BCP is insufficient in durability.

A light receiving device using an organic film capable providing spectral capability into red, green and blue is disclosed, for example, in JP-T-2002-502120, JP-A-2003-158254, JP-A-2003-234460and S. Aihara, Appl. Phys. Lett., vol. 82, p. 511 (2003). For example, the example of JP-A-2003-234460discloses a polysilane film having coumarin 6 dispersed therein having photosensitivity over a blue range at a wavelength of 500 nm, and a polysilane film having rhodamine 6G dispersed therein having photosensitivity in a green range. However, these devices have a low internal quantum efficiency of photoelectric conversion of 1%, and have deteriorated durability. A device using a film of zinc phthalocyanine and tris-8-hydroxyquinoline aluminum as a photoelectric conversion film has insufficient spectral characteristics since it has absorption ranges in a red range and a blue range although the internal quantum efficiency thereof is as relatively high as 20%. Accordingly, in order to use the device as an imaging device, the spectral characteristics, luminescent efficiency and device durability thereof are insufficient, and improvements have been demanded.

### SUMMARY OF THE INVENTION

An object of the invention is to provide such a photoelectric conversion film, a photoelectric conversion device and a imaging device (preferably, a color image sensor) that have a narrow half value width of absorption and are excellent in color reproducibility, to provide such a photoelectric conversion film, a photoelectric conversion device and a imaging device that have a high photoelectric conversion efficiency and are excellent in durability, and to provide an imaging device having spectral sensitivity in a green range.

The objects of the invention are attained by the following means.

(1) A photoelectric conversion device containing an organic photoelectric conversion film intervening between at least two electrodes, the organic photoelectric conversion film containing a positive hole transporting material containing an arylidene compound represented by the following general formula (I) 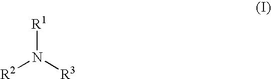
wherein R¹, R² and R³ each independently represents an aryl group, a heterocyclic group or an alkyl group, provided that at least one of R¹, R² and R³ represents an aryl group or a heterocyclic group, at least one of an aryl group and a heterocyclic group represented by R¹, R² and R³ has a substituent containing a group represented by the following general formula (II), and two or more of R¹, R² and R³ may be connected to form a ring 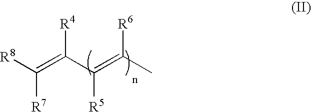
wherein R⁴, R⁵ and R⁶ each independently represents a hydrogen atom or a substituent, R⁷ and R⁸ each independently represents a hydrogen atom or a substituent, at least one of which represents an electron withdrawing group, and n represents 0, 1 or 2.

(2) The photoelectric conversion device as described in the item (1), wherein the group represented by the general formula (II) as a substituent in the general formula (I) is a group represented by the following general formula (III) 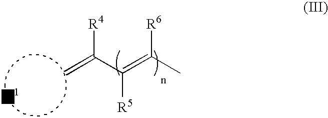
wherein R⁴, R⁵, R⁶ and n have the same meanings as in the general formula (II), and Z¹ represents an atomic group forming a 5- to 7-membered ring.

(3) The photoelectric conversion device as described in the item (1) or (2), wherein the organic photoelectric conversion film contains the positive hole transporting material and an electron transporting material having a maximum wavelength of an absorption spectrum at a maximum wavelength or lower of an absorption spectrum of the positive hole transporting material.

(4) The photoelectric conversion device as described in the item (3), wherein the electron transporting material is a 5- to 7-membered heterocyclic compound having a nitrogen atom, an oxygen atom or a sulfur atom, a condensed aromatic carbocyclic compound, or a metallic complex having a nitrogen-containing heterocyclic compound as a ligand.

(5) The photoelectric conversion device as described in one of the items (1) to (4), wherein the organic photoelectric conversion film has a film absorption spectrum that has a maximum on the longest wavelength side, the film absorption spectrum having a half value width of from 50 to 150 nm.

(6) The photoelectric conversion device as described in one of the items (1) to (5), wherein the photoelectric conversion device further comprising at least one charge transporting layer transporting electrons formed through photoelectric conversion, wherein the charge transporting layer has an absorption spectrum having a longer wavelength end at a wavelength shorter than a longer wavelength end of aluminum quinoline (Alq).

(7) The photoelectric conversion device as described in one of the items (1) to (6), further comprising at least one charge transporting layer transporting electrons formed through photoelectric conversion, wherein the charge transporting layer has an absorption spectrum having a longer wavelength end at a wavelength of 400 nm or less.

(8) The photoelectric conversion device as described in one of the items (1) to (7), wherein the photoelectric conversion device further contains at least one charge transporting layer transporting positive holes or electrons formed through photoelectric conversion, and a filter layer absorbing light having a wavelength of 400 nm or less, and has such a structure that the charge transporting layer does not absorb light owing to light absorption by the filter layer.

(9) The photoelectric conversion device as described in one of the items (1) to (8), wherein the organic photoelectric conversion film has an absorption spectrum having a maximum value at a wavelength of from 510 to 570 nm.

(10) The photoelectric conversion device as described in one of the items (3) to (9), wherein a material constituting the charge transporting layer or the electron transporting material is a compound represented by the following general formula (IV) 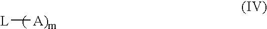
wherein A represents a heterocyclic ring containing two or more aromatic heterocyclic rings condensed to each other, provided that plural heterocyclic rings represented by A are the same as or different from each other; m represents an integer of 2 or more; and L represents a linking group.

(11) The photoelectric conversion device as described in the item (10), wherein the compound represented by the general formula (IV) is a compound represented by the following general formula (VII) 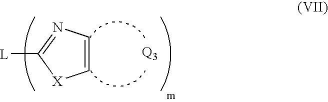
wherein X represents O, S, Se, Te or N—R; R represents a hydrogen atom, an aliphatic hydrocarbon group, an aryl group or a heterocyclic group; Q₃ represents an atomic group forming an aromatic heterocyclic ring (preferably, a nitrogen-containing aromatic heterocyclic ring); m represents an integer of 2 or more; and L represents a linking group.

(12) An imaging device containing the photoelectric conversion device as described in one of the items (1) to (11).

(13) The imaging device as described in the item (12) wherein the imaging device contains a first light receiving part detecting light in a first wavelength range, a second light receiving part detecting light in a second wavelength range, and a third light receiving part detecting light in a third wavelength range, the first light receiving part contains a photoelectric conversion device comprising the organic photoelectric conversion film as described in one of the items (1) to (11), and the second and third light receiving parts each contains a light receiving part formed in a silicon substrate.

### BRIEF DESCRIPTION OF THE DRAWINGS

FIG. 1 is a schematic cross sectional view showing an embodiment of one pixel of a BGR three-layer laminated photoelectric conversion imaging device according to the invention.

1 is a P well layer; 2, 4, 6 are high-concentration impurity regions; 3, 5, 7 are MOS circuits; 8 is a gate insulating film; 9, 10 are insulating films; 11, 14, 16, 19, 24 are transparent electrodes; 12, 17, 22 are electrodes; 13, 18, 23 are photoelectric conversion films; 10, 15, 20, 25 are transparent insulating films; 26 is a light shielding film; and 50 is a semiconductor substrate.

### DETAILED DESCRIPTION OF THE INVENTION

In the photoelectric conversion device according to the invention, the organic photoelectric conversion layer held with at least two electrodes contains a positive hole transporting material containing an arylidene compound represented by the following general formula (I), i.e., contains an arylidene compound represented by the following general formula (I) as a positive hole transporting material.

In the general formula (I), R¹, R² and R³ each independently represents an aryl group, a heterocyclic group or an alkyl group, provided that at least one of R¹, R² and R³ represents an aryl group or a heterocyclic group, and at least one of an aryl group and a heterocyclic group represented by R¹, R² and R³ has a substituent containing a group represented by the following general formula (II). Two or more of R¹, R² and R³ may be connected to form a ring.

In the general formula (II), R⁴, R⁵ and R⁶ each independently represents a hydrogen atom or a substituent. R⁷ and R⁸ each independently represents a hydrogen atom or a substituent, at least one of which represents an electron withdrawing group. n represents 0, 1 or 2.

Examples of the substituent represented by R⁴, R⁵, R⁶, R⁷ and R⁸ in the general formula (II) include an alkyl group (preferably having from 1 to 30 carbon atoms, more preferably from 1 to 20 carbon atoms, and particularly preferably from 1 to 10 carbon atoms, such as methyl, ethyl, iso-propyl, tert-butyl, n-octyl, n-decyl, n-hexadecyl, cyclopropyl, cyclopentyl and cyclohexyl), an alkenyl group (preferably having from 2 to 30 carbon atoms, more preferably from 2 to 20 carbon atoms, and particularly preferably from 2 to 10 carbon atoms, such as vinyl, allyl, 2-butenyl and 3-pentenyl), an alkynyl group (preferably having from 2 to 30 carbon atoms, more preferably from 2 to 20 carbon atoms, and particularly preferably from 2 to 10 carbon atoms, such as propargyl and 3-pentynyl), an aryl group (preferably having from 6 to 30 carbon atoms, more preferably from 6 to 20 carbon atoms, particularly preferably from 6 to 12 carbon atoms, such as phenyl, p-methylphenyl, biphenyl, naphthyl, anthranyl and phenathryl), an amino group (preferably having from 0 to 30 carbon atoms, more preferably from 0 to 20 carbon atoms, and particularly preferably 0 to 10 carbon atoms, such as amino, methylamino, dimethylamino, diethylamino, dibenzylamino, diphenylamino and ditolylamino), an alkoxy group (preferably having from 1 to 30 carbon atoms, more preferably from 1 to 20 carbon atoms, and particularly preferably from 1 to 10 carbon atoms, such as methoxy, ethoxy, butoxy and 2-ethylhexyloxy), an aryloxy group (preferably having from 6 to 30 carbon atoms, more preferably from 6 to 20 carbon atoms, and particularly preferably from 6 to 12 carbon atoms, such as phenyloxy, 1-naphthyloxy and 2-naphthyloxy), an aromatic heterocyclic oxy group (preferably having from 1 to 30 carbon atoms, more preferably from 1 to 20 carbon atoms, and particularly preferably from 1 to 12 carbon atoms, such as pyridyloxy, pyrazyloxy, pyrimidyloxy and quinolyloxy), an acyl group (preferably having from 1 to 30 carbon atoms, more preferably from 1 to 20 carbon atoms, and particularly preferably from 1 to 12 carbon atoms, such as acetyl, formyl and pivaloyl), an alkoxycarbonyl group (preferably having from 2 to 30 carbon atoms, more preferably from 2 to 20 carbon atoms, and particularly preferably from 2 to 12 carbon atoms, such as methoxycarbonyl and ethoxycarbonyl), an aryloxycarbonyl group (preferably having from 7 to 30 carbon atoms, more preferably from 7 to 20 carbon atoms, and particularly preferably from 7 to 12 carbon atoms, such as phenyloxycarbonyl), acyloxy group (preferably having from 2 to 30 carbon atoms, more preferably from 2 to 20 carbon atoms, and particularly preferably from 2 to 10 carbon atoms, such as acetoxy and benzoyloxy), an acylamino group (preferably having from 2 to 30 carbon atoms, more preferably from 2 to 20 carbon atoms, and particularly preferably from 2 to 10 carbon atoms, such as acetylamino and benzoylamino), an alkoxycarbonylamino group (preferably from 2 to 30 carbon atoms, more preferably from2 to 20 carbon atoms, particularly preferably from 2 to 12 carbon atoms, such as methoxycarbonylamino), an aryloxycarbonylamino group (preferably having from 7 to 30 carbon atoms, more preferably from 7 to 20 carbon atoms, and particularly preferably from 7 to 12 carbon atoms, such as phenyloxycarbonylamino), a sulfonylamino group (preferably having from 1 to 30 carbon atoms, more preferably from 1 to 20 carbon atoms, and particularly preferably from 1 to 12 carbon atoms, such as methanesulfonylamino and benzenesulfonylamino), a sulfamoyl group (preferably having from 0 to 30 carbon atoms, more preferably from 0 to 20 carbon atoms, and particularly preferably from 0 to 12 carbon atoms, such as sulfamoyl, methylsulfamoyl, dimethylsulfamoyl and phenylsulfamoyl), a carbamoyl group (preferably having from 1 to 30 carbon atoms, more preferably from 1 to 20 carbon atoms, and particularly preferably from 1 to 12 carbon atoms, such as carbamoyl, methylcarbamoyl, diethylcarbamoyl and phenylcarbamoyl), an alkylthio group (preferably having from 1 to 30 carbon atoms, more preferably from 1 to 20 carbon atoms, and particularly preferably from 1 to 12 carbon atoms, such as methylthio and ethylthio), an arylthio group (preferably having from 6 to 30 carbon atoms, more preferably from 6 to 20 carbon atoms, and particularly preferably from 6 to 12 carbon atoms, such as phenylthio), an aromatic heterocyclic thio group (preferably having from 1 to 30 carbon atoms, more preferably from 1 to 20 carbon atoms, and particularly preferably from 1 to 12 carbon atoms, such as pyridylthio, 2-benzyimidazolylthio, 2-benzoxazolylthio and 2-benzthiazolylthio), a sulfonyl group (preferably having from 1 to 30 carbon atoms, more preferably from 1 to 20 carbon atoms, and particularly preferably from 1 to 12 carbon atoms, such as mesyl and tosyl), a sulfinyl group (preferably having from 1 to 30 carbon atoms, more preferably from 1 to 20 carbon atoms, and particularly preferably from 1 to 12 carbon atoms, such as methanesulfinyl and benzenesulfinyl), an ureido group (preferably having from 1 to 30 carbon atoms, more preferably from 1 to 20 carbon atoms, and particularly preferably from 1 to 12 carbon atoms, such as ureido, methylureido and phenylureido), a phosphoamide group (preferably having from 1 to 30 carbon atoms, more preferably from 1 to 20 carbon atoms, and particularly preferably from 1 to 12 carbon atoms, such as diethylphosphoamide and phenylphosphoamide), a hydroxyl group, a mercapto group, a halogen atom (such as a fluorine atom, a chlorine atom, a bromine atom and an iodine atom), a cyano group, a sulfo group, a carboxyl group, a nitro group, a hydroxamic acid group, a sulfino group, a hydrazino group, an imino group, a heterocyclic group (preferably having from 1 to 30 carbon atoms, and more preferably from 1 to 12 carbon atoms, examples of the hetero atom of which include a nitrogen atom, an oxygen atom and a sulfur atom, such as imidazolyl, pyridyl, quinolyl, furyl, thienyl, piperidyl, morpholino, benzoxazolyl, benzimidazolyl, benzthiazolyl, carbazolyl and azepinyl), and a silyl group (preferably having from 3 to 40 carbon atoms, more preferably from 3 to 30 carbon atoms, and particularly preferably from 3 to 24 carbon atoms, such as trimethylsilyl and triphenylsilyl). These substituents may be further substituted.

R⁴, R⁵ and R⁶ each preferably represents a hydrogen atom, an alkyl group, an alkenyl group, an aryl group, an alkoxy group, a halogen atom, a cyano group, a sulfonyl group, a sulfinyl group or a heterocyclic group, more preferably a hydrogen atom, an alkyl group or an alkenyl group, and particularly preferably a hydrogen atom.

Preferred examples of the substituent represented by R⁷ and R⁸ include an alkyl group, an alkenyl group, an aryl group, an alkoxy group, an aryloxy group, a carbonyl group, a thiocarbonyl group, an oxycarbonyl group, an acylamino group, a carbamoyl group, a sulfonylamino group, a sulfamoyl group, a sulfonyl group, a sulfinyl group, a phosphoryl group, an imino group, a cyano group, a halogen atom, a silyl group and an aromatic heterocyclic group, more preferably an electron withdrawing group having a Hammett's σp value (sigma para value) of 0.2 or more, further preferably an aryl group, an aromatic heterocyclic group, a cyano group, a carbonyl group, a thiocarbonyl group, an oxycarbonyl group, a carbamoyl group, a sulfamoyl group, a sulfonyl group, an imino group, a halogen atom and an electron withdrawing cyclic group formed by connecting R⁷ and R⁸, particularly preferably an aromatic heterocyclic group, a carbonyl group, a cyano group, an imino group and an electron withdrawing cyclic group formed by connecting R⁷ and R⁸, and most preferably an electron withdrawing cyclic group formed by connecting R⁷ and R⁸, which is preferably represented by the general formula (III). It is also preferred that at least one of R⁷ and R⁸ is an electron withdrawing group (preferably an electron withdrawing group having a Hammett's σp value of 0.2 or more).

In the general formula (III), Z¹ represents an atomic group forming a 5- to 7-membered ring (preferably a 5- or 6-membered ring). The ring to be formed is preferably such a ring that is generally used as an acidic nucleus in a merocyanine colorant, and specific examples thereof include the following (a) to (r):

(a) a 1,3-dicarbonyl nucleus, such as 1,3-indanedione nucleus, 1,3-cyclohexanedione, 5,5-dimethyl-1,3-cyclohexanedione and 1,3-dioxane-4,6-dione,

(b) a pyrazolinone nucleus, such as 1-phenyl-2-pyrazolin-5-one, 3-methyl-1-phenyl-2-pyrazolin-5-one and 1-(2-benzothiazoyl)-3-methyl-2-pyrazolin-5-one,

(c) an isoxazolinone nucleus, such as 3-phenyl-2-isoxaaolin-5-one and 3-methyl-2-oxazolin-5-one,

(d) an oxyindole nucleus, such as 1-alkyl-2,3-dihydro-2-oxyindole,

(e) a 2,4,6-triketohexahydropyrimidine nucleus, such as barbituric acid, 2-thiobarbituric acid and a derivative thereof (examples of the derivative include a 1-alkyl derivative, such as 1-methyl and 1-ethyl, a 1,3-dialkyl derivative, such as 1,3-dimethyl, 1,3-diethyl and 1,3-dibutyl, a 1,3-diaryl derivative, such as 1,3-diphenyl, 1,3-di(p-chlorophenyl) and 1,3-di(p-ethoxycarbonylphenyl), a 1-alkyl-1-aryl derivative, such as 1-ethyl-3-phenyl, and a 1,3-diheterocyclic ring-substituted derivative, such as 1,3-di(2-pyridyl)),

(f) a 2-thio-2,4-thiazolidinedione nucleus, such as rhodanine and a derivative thereof (examples of the derivative include a 3-alkylrhodanine, such as 3-methylrhodanine, 3-ethylrhodanine and 3-allylrhodanine, a 3-arylrhodanine, such as 3-phenylrhodanine, and a 3-heterocyclic ring-substituted rhodanine, such as 3-(2-pyridyl)rhodanine),

(g) a 2-thio-2,4-oxazolidinedione (2-thio-2,4-(3H,5H)-oxazoldione) nucleus, such as 3-ethyl-2-thio-2,4-oxazolidinedione,

(h) a thianaphthenone nucleus, such as 3(2H)-thianaphthenone-1,1-dioxide,

(i) a 2-thio-2,5-thiozolidinedione nucleus, such as 3-ethyl-2-thio-2,5-thiazolidinedione,

(j) a 2,4-thiazolidinedione nucleus, such as 2,4-thiazolidinedione, 3-ethyl-2,4-thiazolidinedione and 3-phenyl-2,4-thiazolidinedione,

(k) a thiazolin-4-one nucleus, such as 4-thiazolinone and 2-ethyl-4-thiazolinone,

(l) a 4-thiazolidinone nucleus, such as 2-ethylmercapto-5-thiazolin-4-one and 2-alkylphenylamino-5-thiazolin-4-one,

(m) a 2,4-imidazolidinedione (hydantoin) nucleus, such as 2,4-imidazolidinedione and 3-ethyl-2,4-imidazolidinedione,

(n) a 2-thio-2,4-imidazolidinedione (2-thiohydantoin) nucleus, such as 2-thio-2,4-imidazolidinedione and 3-ethyl-2-thio-2,4-imidazolidinedione,

(o) an imidazolin-5-one nucleus, such as 2-propylmercapto-2-imidazolin-5-one,

(p) a 3,5-pyrazolidinedione nucleus, such as 1,2-diphenyl-3,5-pyrazolidinedione and 1,2-dimethyl-3,5-pyrazolidinedione,

(q) a benzothiophen-3-one nucleus, such as benzothiophen-3-one, oxobenzothiophen-3-one and dioxobenzothiophen-3-one, and

(r) an indanone nucleus, such as 1-indanone, 3-phenyl-1-indanone, 3-methyl-1-indanone, 3,3-diphenyl-1-indanone and 3,3-dimethyl-1-indanone.

Preferred examples of the ring formed by Z¹ include a 1,3-dicarbonyl nucleus, a pyrazolinone nucleus, a 2,4,6-triketohexahydropyrimidine nucleus (including a thioketone derivative), a 2-thio-2,4-thazolidinedione nucleus, a 2-thio-2,4-oxazolidinedione nucleus, a 2-thio-2,5-thiazolidinedione nucleus, a 2,4-thazolidinedione nucleus, a 2,4-imidazolidinedione nucleus, a 2-thio-2,4-imidazolidinedione nucleus, a 2-imidazolin-5-one nucleus, a 3,5-pyrazolidinedione nucleus, a benzothiophen-3-one nucleus and an indanone nucleus, more preferably a 1,3-dicarbonyl nucleus, a 2,4,6-triketohexahydropyrimidine nucleus (including a thioketone derivative), a 3,5-pyrazolidinedione nucleus, a benzothiophen-3-one nucleus and an indanone nucleus, particularly preferably a 1,3-dicarbonyl nucleus and a 2,4,6-triketohexahydropyrimidine nucleus (including a thioketone derivative), and most preferably a 1,3-indanedione nucleus.

In the general formula (II), n represents 0, 1 or 2, preferably 0 or 1, and more preferably 0.

Examples of the compound represented by the general formula (I) that are preferably used in the invention are shown below, but the invention is not limited to them.

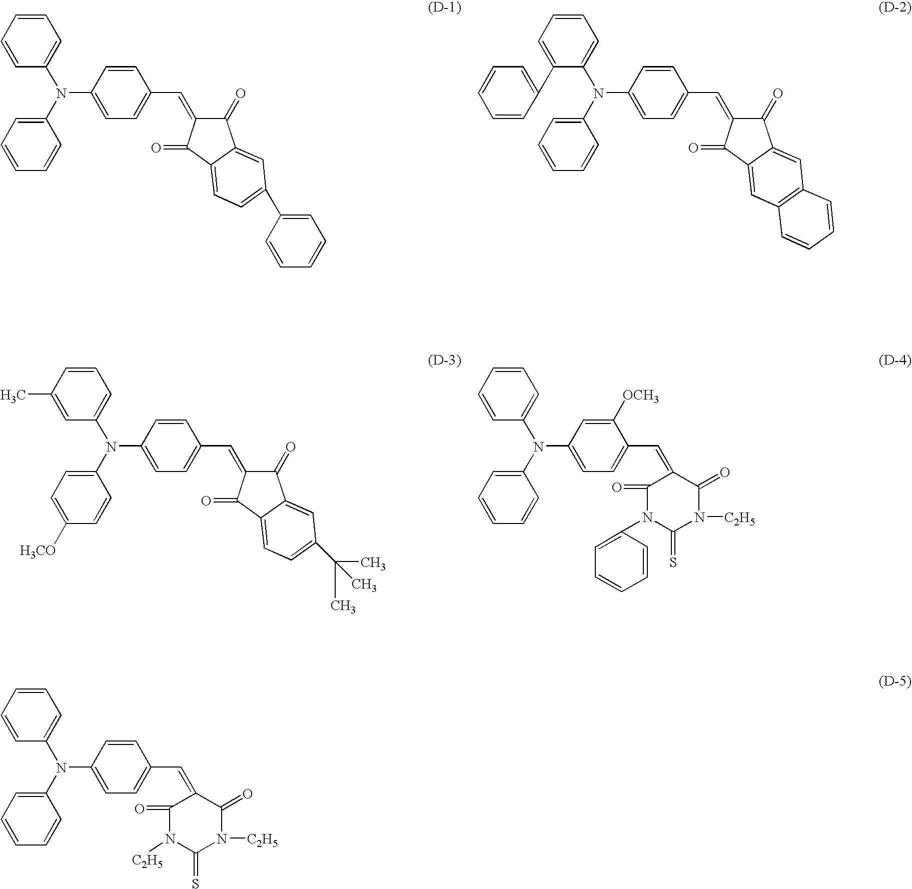

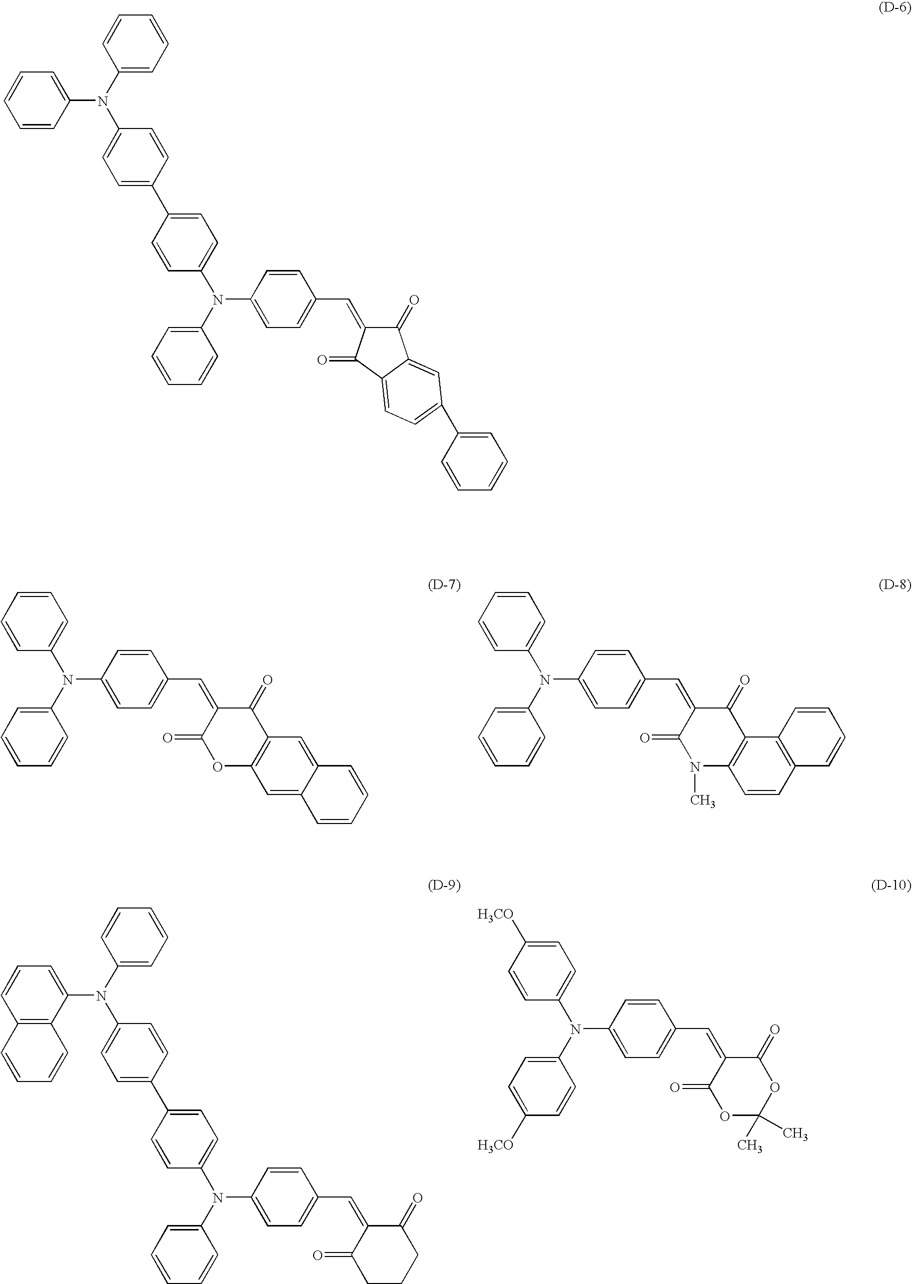

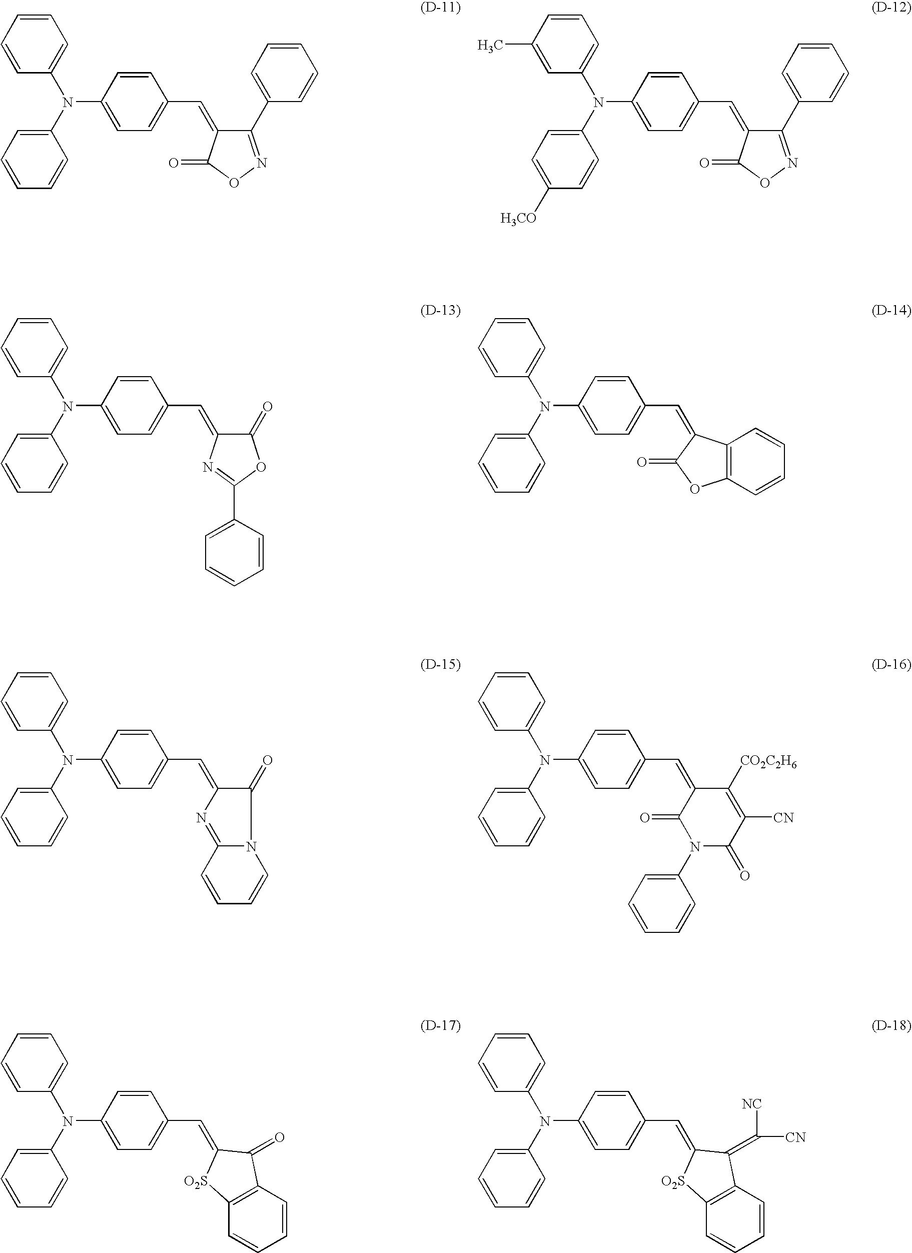

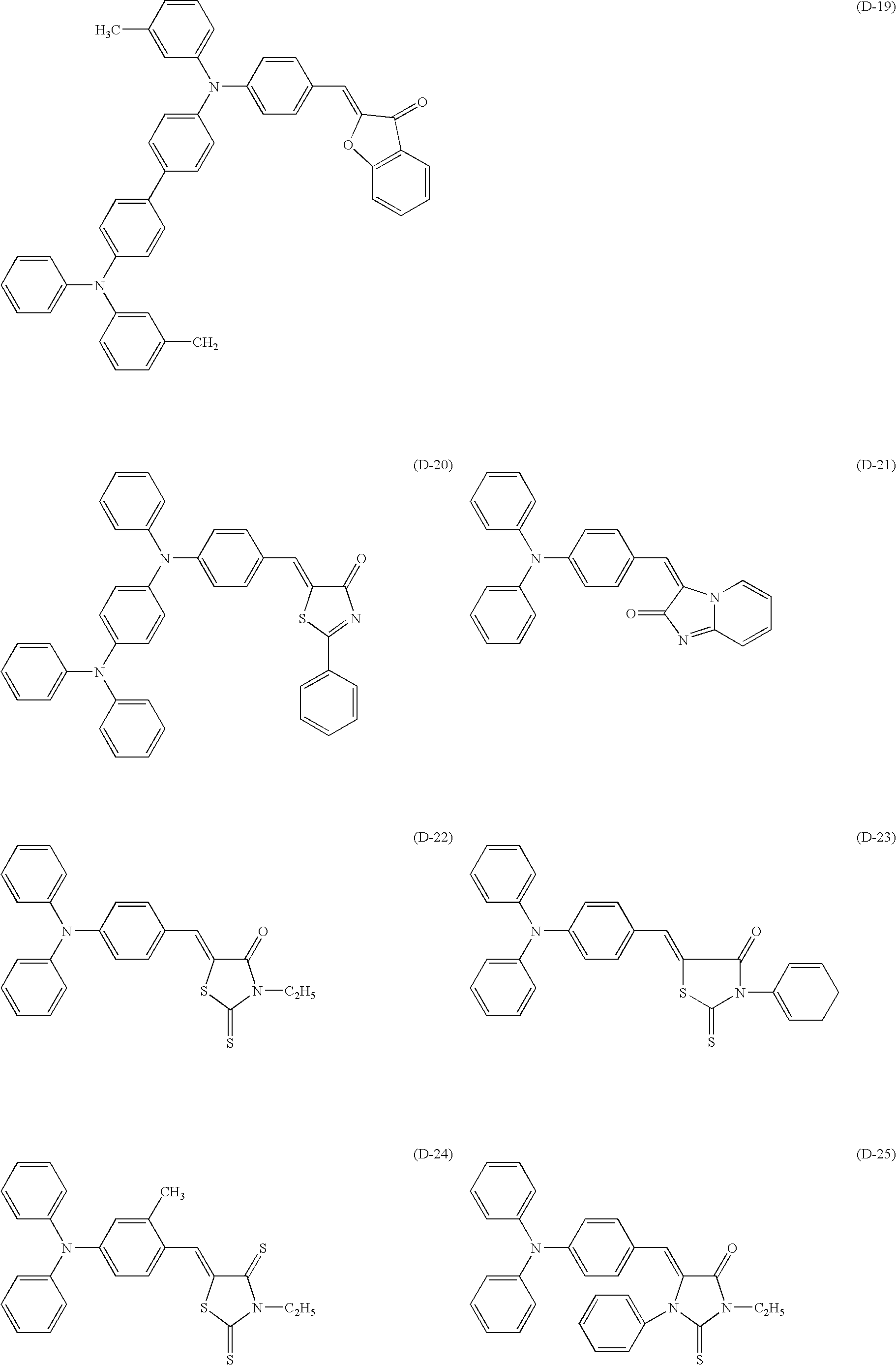

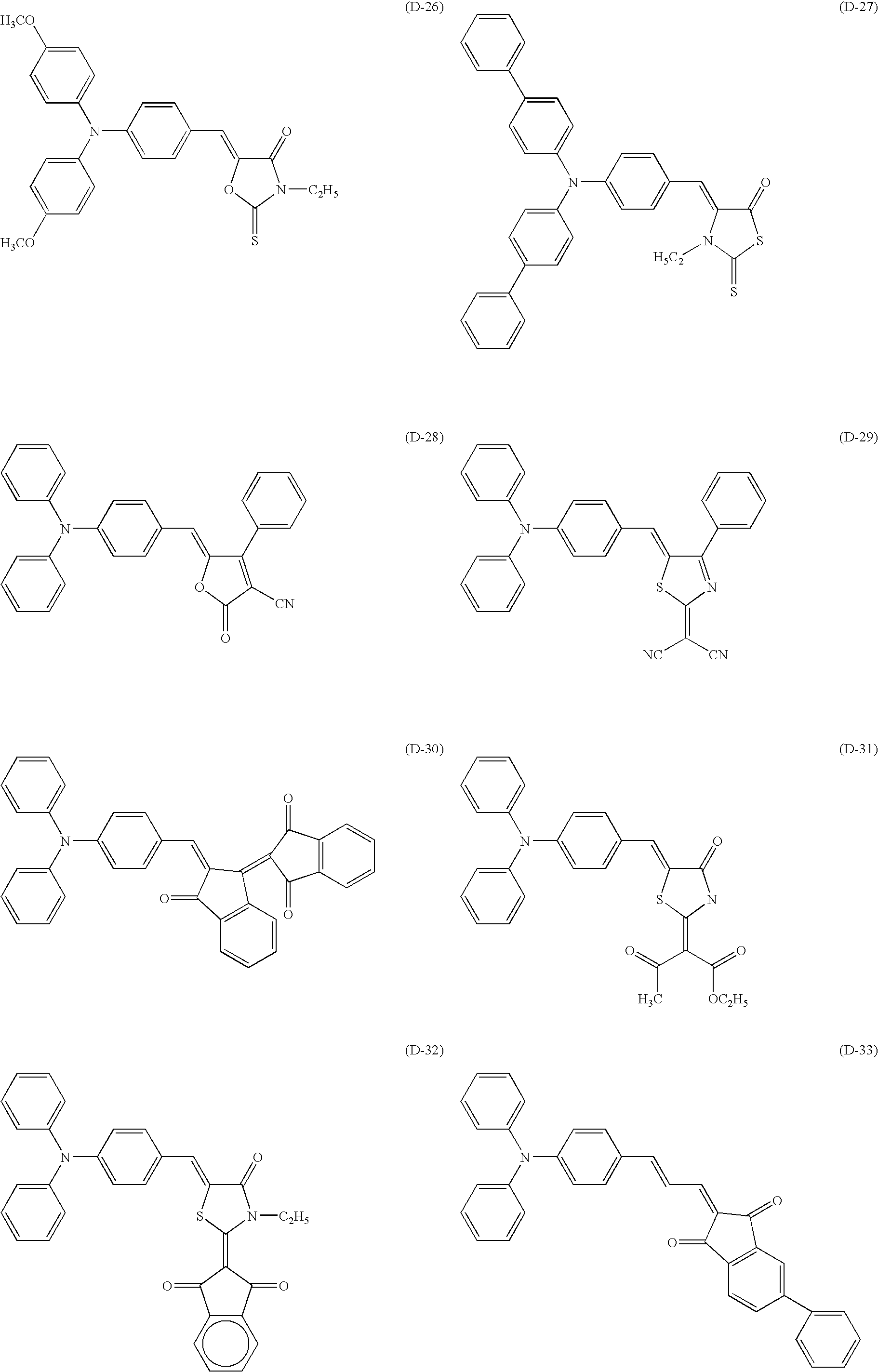

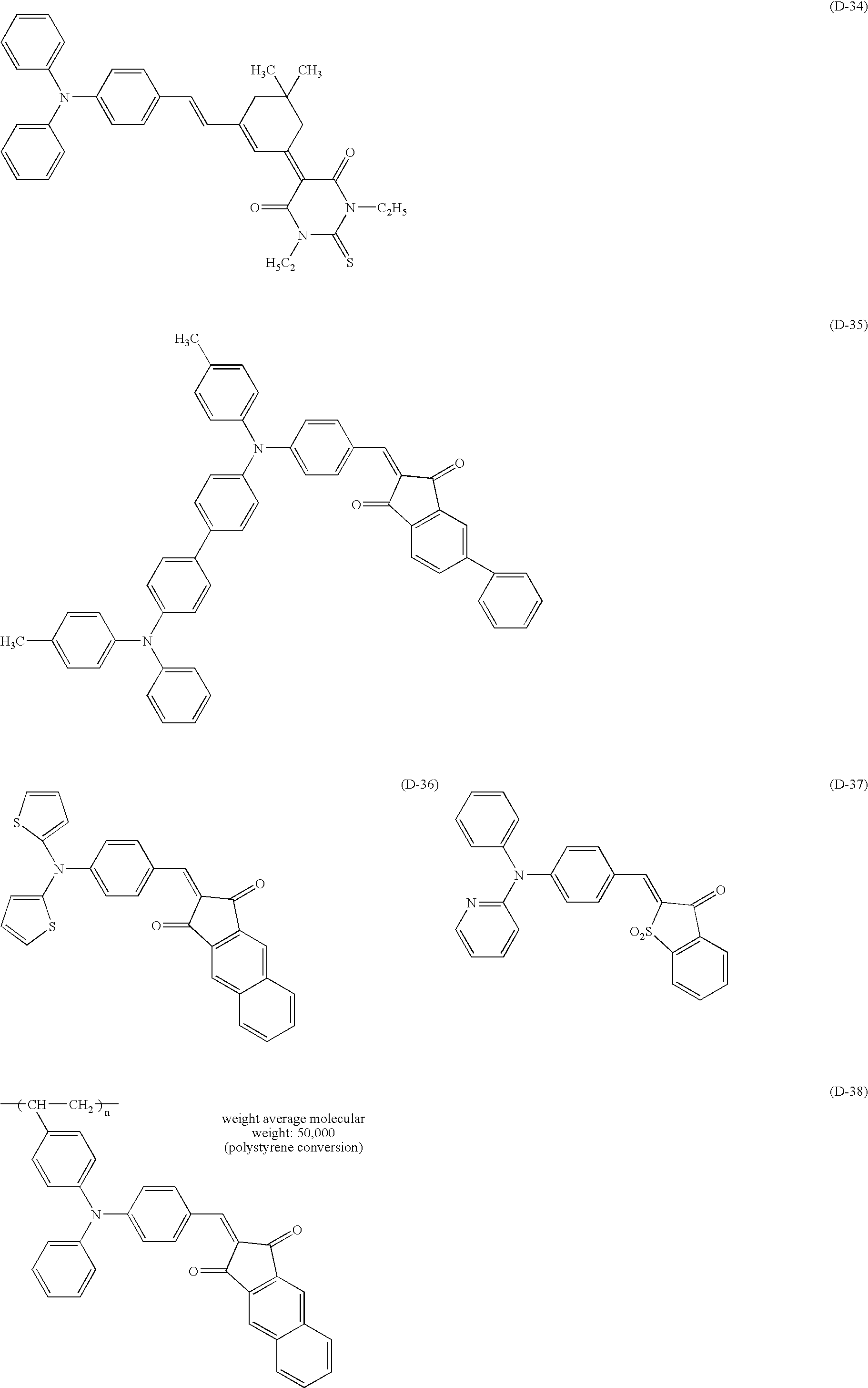

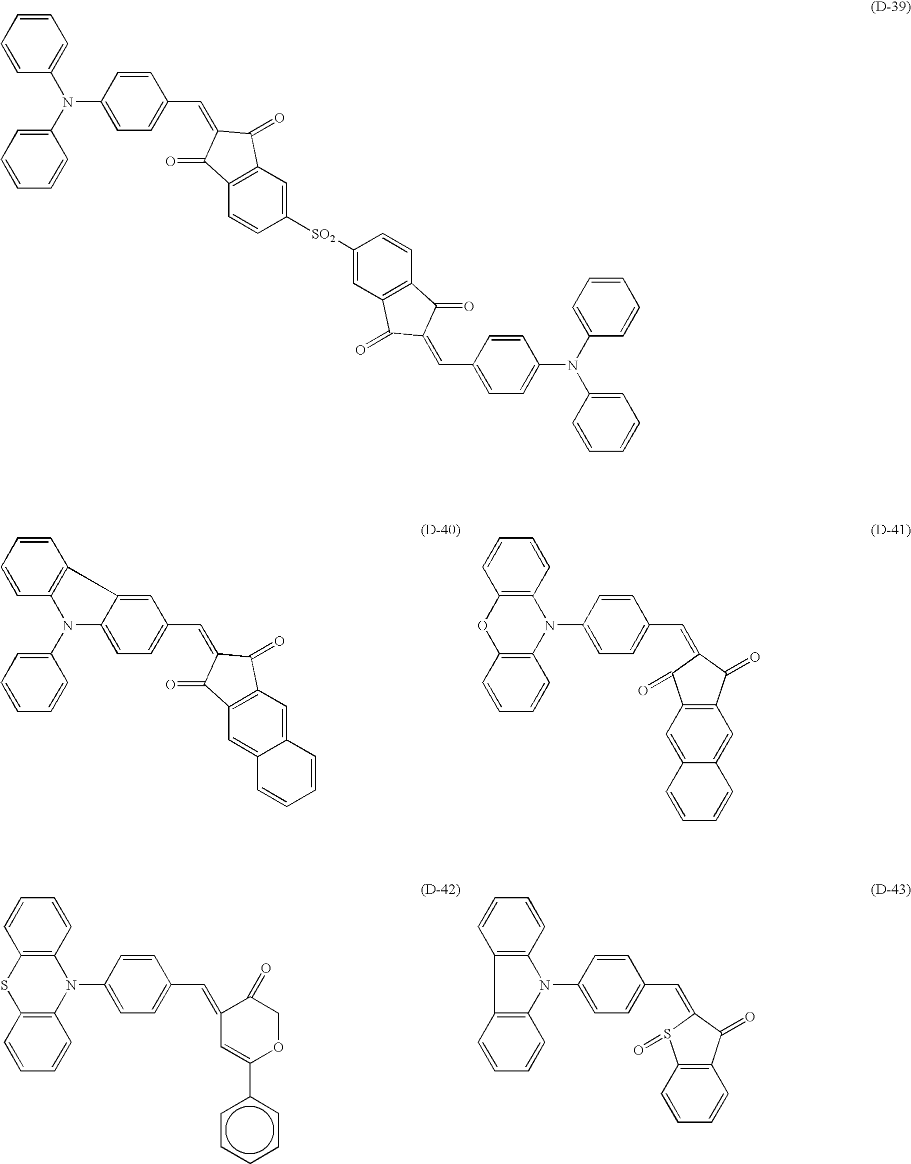

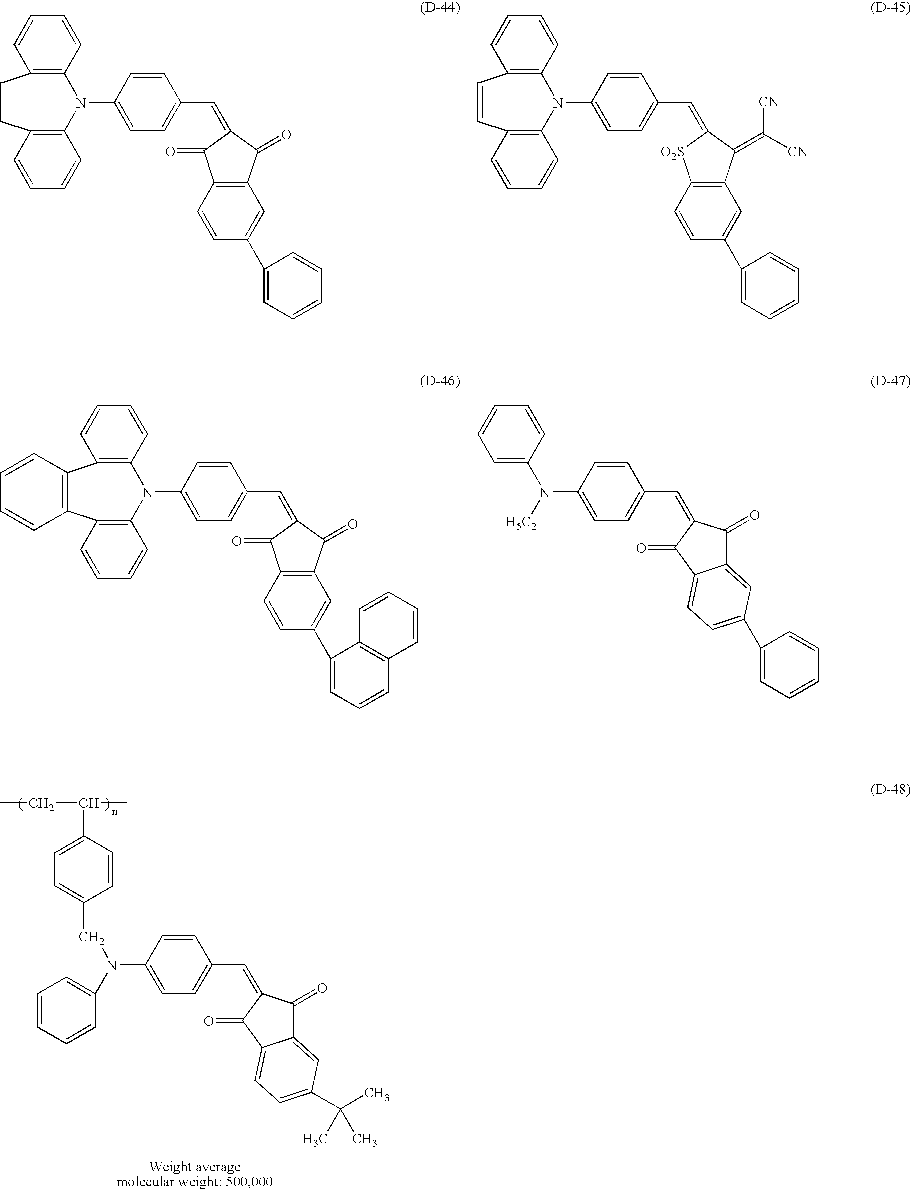

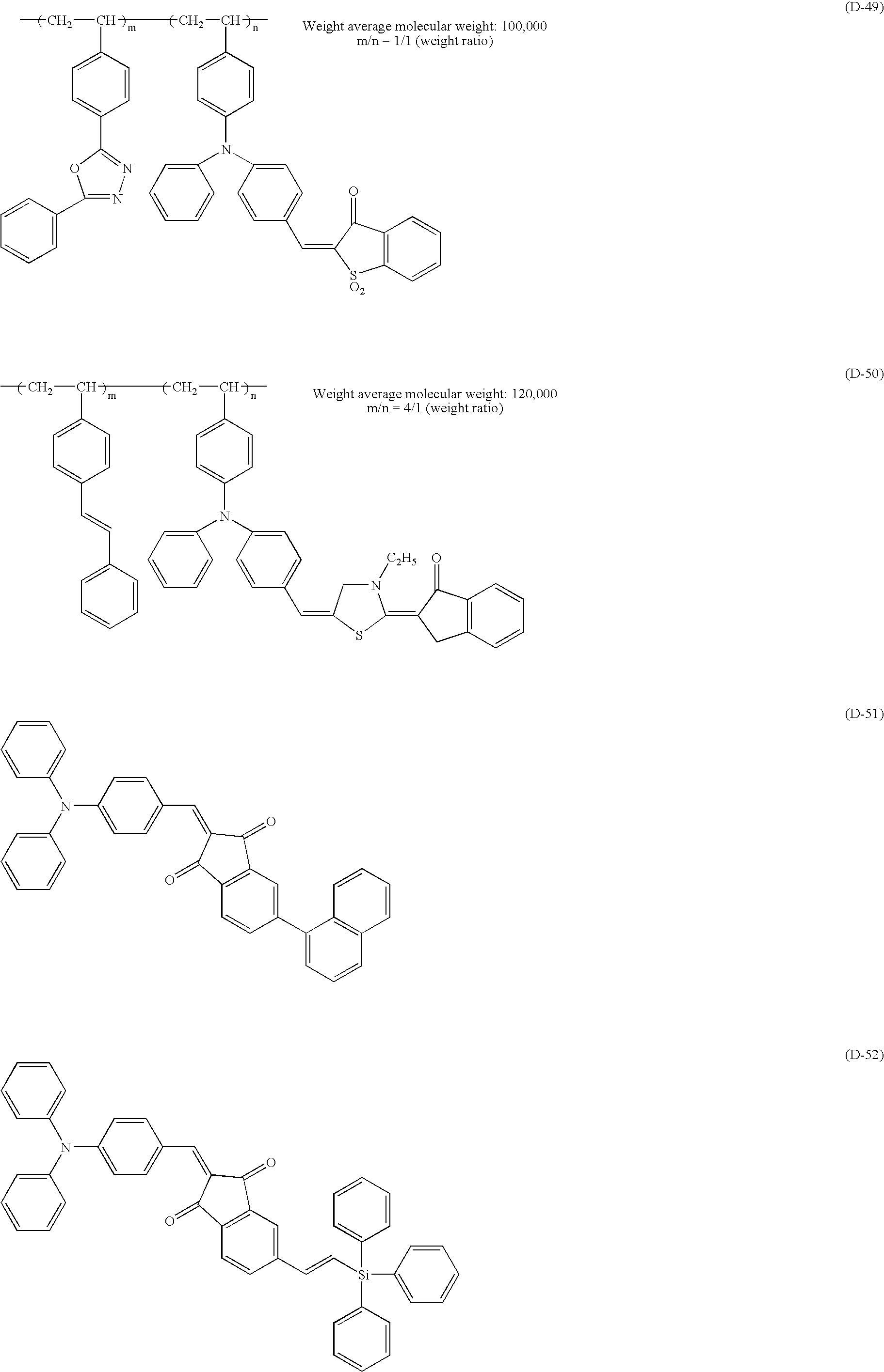

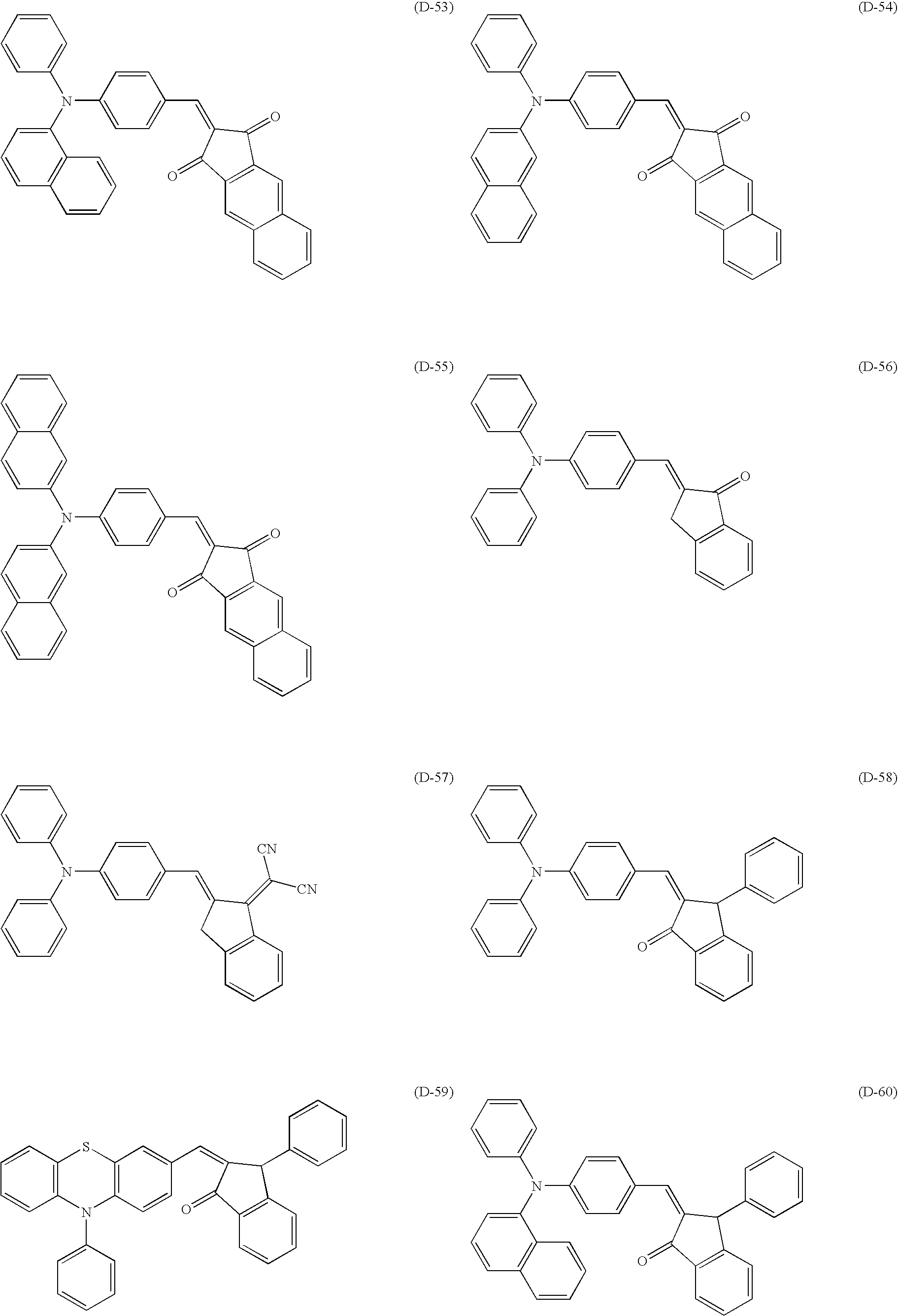

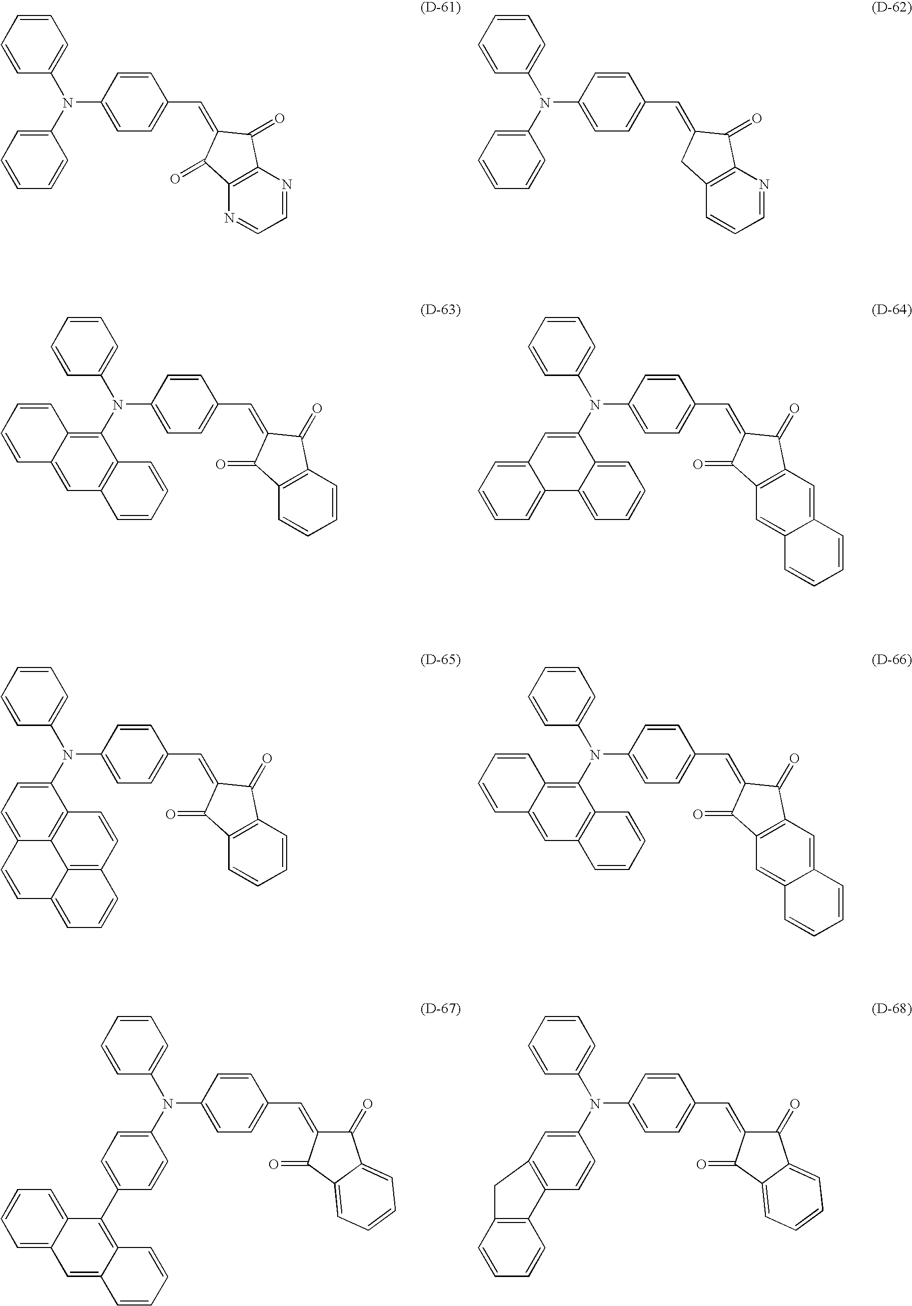

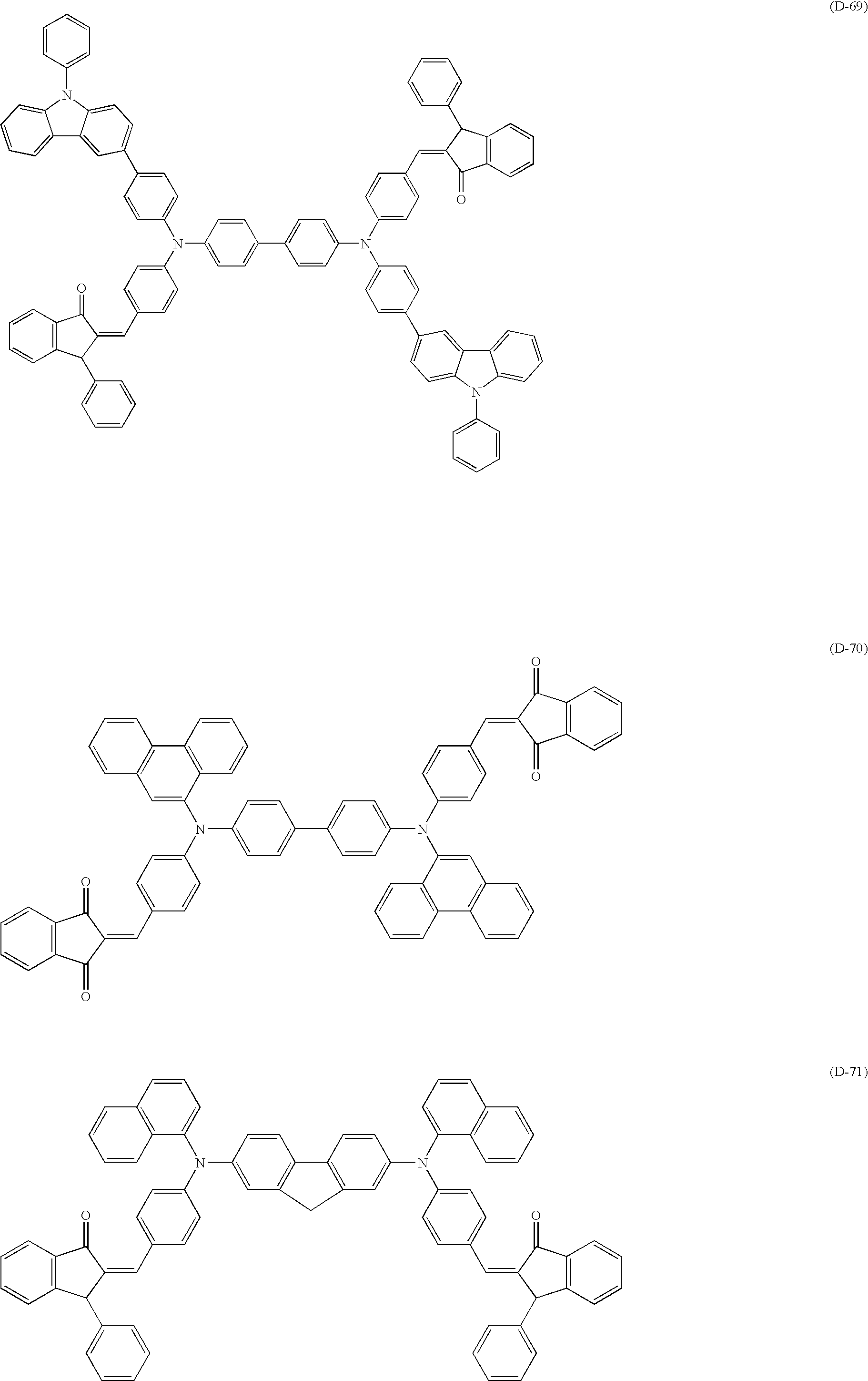

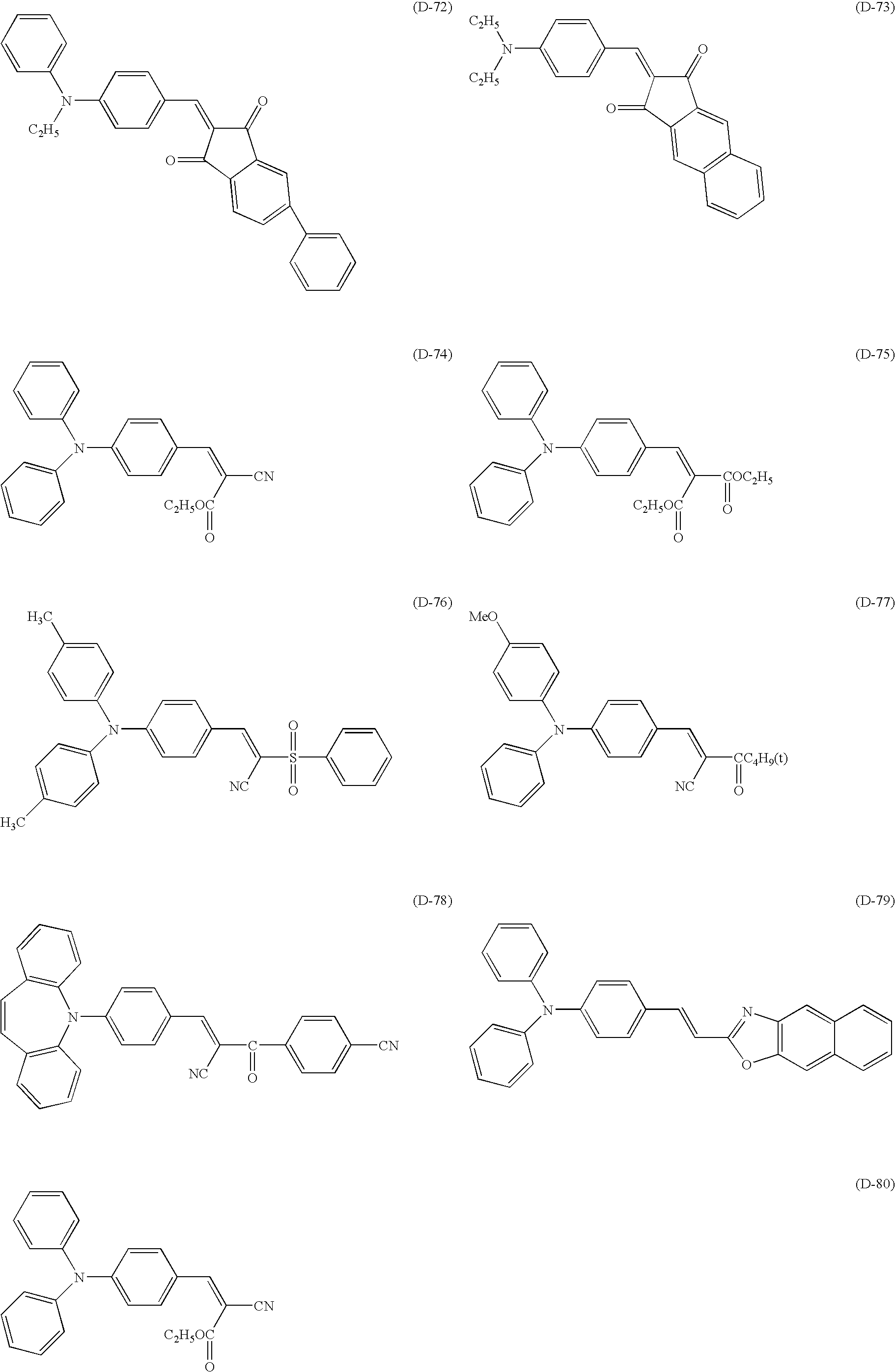

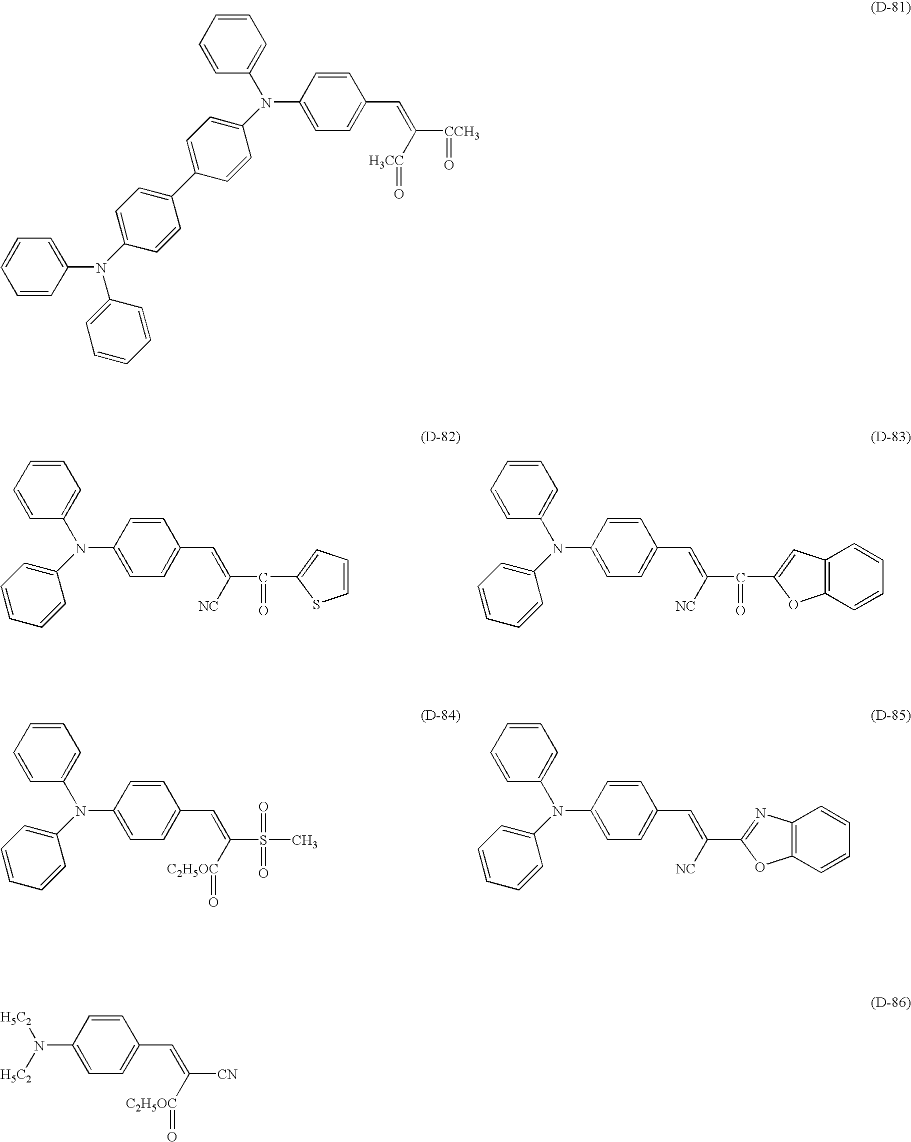

The photoelectric conversion film of the invention may further contain an organic p-type compound an organic n-type compound described below.

The organic p-type semiconductor (compound) is a donative organic semiconductor (compound), which means an organic compound having such a nature that it tends to donate electrons, which is mainly represented by a positive hole transporting organic compound. More specifically, upon making two organic materials in contact to each other, the organic p-type compound is such an organic compound that has a smaller ionization potential. Therefore, any organic compound having an electron donative nature can be used as the donative organic compound. Examples thereof include a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a cyanine compound, a merocyanine compound, an oxonol compound, a polyamine compound, an indole compound, a pyrrole compound, a pyrazole compound, a polyarylene compound, a condensed aromatic carbocyclic compound (such as a naphthalene derivative, an anthracene derivative, a phenanthrene derivative, a tetracene derivative, a pyrene derivative, a perylene derivative and a foluorantene derivative), and a metallic complex having a nitrogen-containing heterocyclic compound as a ligand. The donative organic semiconductor is not limited to these examples and may be such an organic compound that has a smaller ionization potential than that of the organic compound used as the n-type (acceptive) compound, as described hereinabove.

The organic n-type semiconductor (compound) is an acceptive organic semiconductor (compound), which means an organic compound having such a nature that it tends to accept electrons, which is mainly represented by an electron transporting organic compound. More specifically, upon making two organic materials in contact to each other, the organic n-type compound is such an organic compound that has a larger electron affinity. Therefore, any organic compound having an electron acceptive nature can be used as the acceptive organic compound. Examples thereof include a condensed aromatic carbocyclic compound (such as a naphthalene derivative, an anthracene derivative, a phenanthrene derivative, a tetracene derivative, a pyrene derivative, a perylene derivative and a foluorantene derivative), a 5- to 7-membered heterocyclic compound containing a nitrogen atom, an oxygen atom or a sulfur atom (such as pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, betnzothiazole, carbazole, purine, triazolopyridazine, triazolopyrimidine, tetrazaindene, oxadiazole, imidazopyridine, pyralidine, pyrrolopyridine, thiadizolopyridine, dibenzazepine and tribenzazepine), a polyarylene compound, a fluorene compound, a cyclopentadiene compound, a silyl compound, and a metallic complex having a nitrogen-containing heterocyclic compound as a ligand. The acceptive organic semiconductor is not limited to these examples and may be such an organic compound that has a larger electron affinity than that of the organic compound used as the donative compound, as described hereinabove.

The p-type organic colorant and the n-type organic colorant may be selected from any compound, and preferred examples thereof include a cyanine colorant, a styryl colorant, a hemicyanine colorant, a merocyanine colorant (including zero-methine merocyanine (simple merocyanine) a trinucleus merocyanine colorant, a tetranucleus merocyanine colorant, a rhodacyanine colorant, a complex cyanine colorant, a complex merocyanine colorant, an allopolar colorant, an oxonol colorant, a hemioxonol colorant, a squalirium colorant, a croconium colorant, an azamethine colorant, a coumarin colorant, an arylidene colorant, an anthraquinone colorant, a triphenylmethane colorant, an azo colorant, an azomethine colorant, a spiro compound, a metallocene colorant, a fluorenone colorant, a fulgide colorant, a perylene colorant, a phenazine colorant, a phenothiazine colorant, a quinone colorant, an indigo colorant, a diphenylmethane colorant, a polyene colorant, an acridine colorant, an acridinone colorant, a diphenylamine colorant, a quinacridone colorant, a quinophthalone colorant, a phenoxadine colorant, a phthaloperylene colorant, a porphyrin colorant, a chlorophyll colorant, a phthalocyanine colorant, a metallic complex colorant, and a condensed aromatic carbocyclic compound (such as a naphthalene derivative, an anthracene derivative, a phenanthrene derivative, a tetracene derivative, a pyrene derivative, a perylene derivative and a foluorantene derivative).

The layer containing the organic compound is formed by a dry film forming method or a wet film forming method. Specific examples of the dry film forming method include a physical vapor phase growing method, such as a vacuum deposition method, an ion plating method and MBE method, and a CVD method, such as a plasma polymerization method. Examples of the wet film forming method include a casting method, a spin coating method, a dipping method and an LB method.

In the case where a polymer compound is used as at least one of the p-type semiconductor (compound) or the n-type semiconductor (compound), it is preferably formed into a film by the wet film forming method, by which the film can be easily formed. In the case where the dry film forming method, such as vapor deposition, is applied thereto, a polymer is difficult to use due to the possibility of decomposing the polymer, but an oligomer can be preferably used instead. In the case where a low molecular weight compound is used, the film is preferably formed by the dry film forming method, such as a co-deposition method.

The electron transporting material used in the device of the invention will be described. Examples of the electron transporting material include those exemplified for the organic n-type semiconductor (compound), preferably a 5- to 7-membered heterocyclic compound containing a nitrogen atom, an oxygen atom or a sulfur atom (to which a heterocyclic ring and/or a carbocyclic ring may be condensed), a condensed aromatic carbocyclic compound, and a metallic complex having a nitrogen-containing heterocyclic compound as a ligand, more preferably a metallic complex having a nitrogen-containing heterocyclic compound as a ligand and a 5- to 7-membered heterocyclic compound containing a nitrogen atom, an oxygen atom or a sulfur atom (to which a heterocyclic ring and/or a carbocyclic ring may be condensed), further preferably a compound represented by the general formula (IV), a compound represented by the general formula (V) and a compound represented by the general formula (VI), and particularly preferably a compound represented by the general formula (IV) and most preferably a compound represented by the general formula (VII).

The compound represented by the general formula (IV) will be described. A represents a heterocyclic ring containing two or more aromatic heterocyclic rings condensed to each other, and plural heterocyclic rings represented by A may be the same as or different from each other. The heterocyclic group represented by A is preferably a heterocyclic group formed by condensing 5- or 6-membered aromatic heterocyclic rings, and more preferably formed by condensing from 2 to 6, further preferably from 2 or 3, and particularly preferably 2, aromatic heterocyclic rings. Preferred examples of the hetero atom include N, O, S, Se, and Te atoms, more preferably N, O and S atoms, and further preferably an N atom. Specific examples of the aromatic heterocyclic ring constituting the heterocyclic group represented by A include furan, thiophene, pyrrole, imidazole, pyrazole, pyridine, pyrazine, pyrimidine, pyridazine, thiazole, oxazole, isothiazole, isoxazole, thiadiazole, oxadiazole, triazole, selenazole and tellurazole, preferably imidazole, pyrazole, pyridine, pyrazine, pyrimidine, pyridazine, thiazole and oxazole, and more preferably imidazole, thiazole, oxazole, pyridine, pyrazine, pyrimidine and pyridazine.

Specific examples of the condensed ring represented by A include indoridine, purine, pteridine, carboline, pyrroloimidazole, pyrrolotriazole, pyrazoimidazole, pyrazolotriazole, pyrazolopyrimidine, pyrazolotriazine, triazolopyridine, tetrazaindene, pyrroloimidazole, pyrrolotriazole, imidazoimidazole, imidazopyridine, imidazopyrazine, imidazopyrimiaine, imidazopyridazine, oxazolopyridine, oxazolopyrazine, oxazolopyrimidine, oxazolopyridazine, thiazolopyridine, thiazolopyrazine, thiazolopyrimidine, thiazolopyridazine, pyridinopyrazine, pyrazinopyrazine, pyrazinopyridazine, naphthylidine and imidazotriazine, preferably imidazopyridine, imidazopyrazine, imidazopyrimidine, imidazopyridazine, oxazolopyridine, oxazolopyrazine, oxazolopyrimidine, oxazolopyridazine, thiazolopyridine, thiazolopyrazine, thiazolopyrimidine, thiazolopyridazine, pyridinopyrazine and pyrazinopyrazine, further preferably imidazopyridine, oxazolopyridine, thiazolopyridine, pyridinopyrazine and pyrazinopyrazine, and particularly preferably imidazopyridine.

The heterocyclic group represented by A may be further condensed with another ring and may have a substituent.

Preferred specific examples of the substituent on the heterocyclic group represented by A include an alkyl group, an alkenyl group, an alkenyl group, an alkynyl group, an aryl group, an amino group, an alkoxy group, an aryloxy group, an acyl group, an alkoxycarbonyl group, an aryloxycarbonyl group, an acyloxy group, an acylamino group, an alkoxycarbonylamino group, an aryloxycarbonylamino group, a sufonylamino group, a sulfamoyl group, a carbamoyl group, an alkylthio group, an arylthio group, a sulfonyl group, a halogen atom, a cyano group and a heterocyclic group, more preferably an alkyl group, an alkenyl group, an aryl group, an alkoxy group, an aryloxy group, a halogen atom, a cyano group and a heterocyclic group, further preferably an alkyl group, an aryl group, an alkoxy group, an aryloxy group and an aromatic heterocyclic group, and particularly preferably an alkyl group, an aryl group, an alkoxy group and an aromatic heterocyclic group.

m represents an integer of 2 or more, preferably from 2 to 8, more preferably from 2 to 6, further preferably from 2 to 4, particularly preferably 2 or 3, and most preferably 3.

L represents a linking group. Preferred examples of the linking group represented by L include a single bond and a linking group containing C, N, O, S, Si and Ge, more preferably a single bond, an alkylene group, an alkenylene group, an alkynylene group, an arylene group, a divalent heterocyclic ring (preferably an aromatic heterocyclic ring, and more preferably an aromatic heterocyclic ring formed with an azole ring, a thiophene ring and a furan ring), N, and a group formed of these groups or atoms, and further preferably an arylene group, a divalent aromatic heterocyclic ring, N, and a group formed of these groups or atoms. The linking group represented by L may have a substituent, and examples of the substituent include those exemplified as the substituent on the heterocyclic group represented by A.

Specific examples of thee linking group represented by L include a single bond and those disclosed in paragraphs 0037 to 0040 of Japanese Patent Application No. 2004-082002.

The compound represented by the general formula (IV) is a compound represented by the general formula (VII).

The general formula (VII) will be described. m and L have the same meanings as those in the general formula (IV), and the preferred ranges thereof are also the same. X represents O, S, Se, Te or N—R, and R represents a hydrogen atom, an aliphatic hydrocarbon group, an aryl group or a heterocyclic group. Q₃ represents an atomic group forming an aromatic heterocyclic ring.

Preferred examples of the aliphatic hydrocarbon group represented by R include an alkyl group (preferably having from 1 to 20 carbon atoms, more preferably from 1 to 12 carbon atoms, and particularly preferably from 1 to 8 carbon atoms, such as methyl, ethyl, iso-propyl, tert-butyl, n-octyl, n-decyl, n-hexadecyl, cyclopropyl, cyclopentyl and cyclohexyl), an alkenyl group (preferably having from 2 to 20 carbon atoms, more preferably from 2 to 12 carbon atoms, and particularly preferably from 2 to 8 carbon atoms, such as vinyl, allyl, 2-butenyl and 3-pentenyl) and an alkynyl group (preferably having from 2 to 20 carbon atoms, more preferably from 2 to 12 carbon atoms, and particularly preferably from 2 to 8 carbon atoms, such as propargyl and 3-pentynyl), and more preferably an alkyl group and an alkenyl group.

The aryl group represented by R preferably has from 6 to 30 carbon atoms, more preferably from 6 to 20 carbon atoms, and particularly preferably from 6 to 12 carbon atoms, and examples thereof include phenyl, 2-methylphenyl, 3-methylphenyl, 4-methylphenyl, 4-methoxyphenyl, 3-trifluoromethylphenyl, pentafluorophenyl, 2-biphenylyl, 3-biphenylyl, 4-biphenylyl, 1-naphthyl, 2-naphthyl and 1-pyrenyl.

The heterocyclic group represented by R is preferably a monocyclic or condensed ring heterocyclic group (preferably a heterocyclic group having from 1 to 20 carbon atoms, more preferably from 1 to 12 carbon atoms, and further preferably from 2 to 10 carbon atoms), and more preferably an aromatic heterocyclic group containing at least one of a nitrogen atom, an oxygen atom, a sulfur atom and a selenium atom. Specific examples of the heterocyclic group represented by R include pyrrolidine, piperidine, pyrrole, furan, thiophene, imidazoline, imidazole, benzimidazole, naphthoimidazole, thiazolidine, thiazole, benzthiazole, naphthothiazole, isothiazole, oxazoline, oxazole, benzoxazole, naphthoxazole, isoxazole, selenazole, benzselenazole, naphthoselenazole, pyridine, quinoline, isoquinoline, indole, indolenine, pyrazole, pyrazine, pyrimidine, pyridazine, triazine, indazole, purine, phthalazine, naphthylidine, quinoxaline, quinazoline, cinnoline, pteridine, phenanthridine, pteridine, phenanthroline and tetrazaindene, preferably furan, thiophene, pyridine, quinoline, pyrazine, pyrimidine, pyridazine, triazine, phthalazine, naphthylidine, quinoxaline and quinazoline, more preferably furan, thiophene, pyridine and quinoline, and particularly preferably quinoline.

The aliphatic hydrocarbon group, the aryl group and the heterocyclic group represented by R may have a substituent. Examples of the substituent include those exemplified as the substituent on the heterocyclic group represented by A in the general formula (IV), and the preferred examples thereof are the same. R preferably represents an alkyl group, an aryl group or an aromatic heterocyclic group, preferably an aryl group or an aromatic heterocyclic group, and further preferably an aryl group or an aromatic azole group.

X preferably represents O, S or N—R, more preferably O or N—R, further preferably N—R, and particularly preferably N—Ar, wherein Ar represents an aryl group or an aromatic azole group, more preferably an aryl group having from 6 to 30 carbon atoms or an aromatic azole group having from 2 to 30 carbon atoms, further preferably an aryl group having from 6 to 20 carbon atoms or an aromatic azole group having from 2 to 16 carbon atoms, and particularly preferably an aryl group having from 6 to 12 carbon atoms or an azole group having from 2 to 10 carbon atoms.

Q₃ represents an atomic group forming an aromatic heterocyclic ring. The aromatic heterocyclic ring formed with Q₃ is preferably a 5- or 6-membered aromatic heterocyclic ring, more preferably a 5- or 6-membered nitrogen-containing aromatic heterocyclic ring, and further preferably a 6-membered nitrogen-containing aromatic heterocyclic ring. Specific examples of the aromatic heterocyclic ring formed with Q₃ include furan, thiophene, pyran, pyrrole, imidazole, pyrazole, pyridine, pyrazine, pyrimidine, pyridazine, thiazole, oxazole, isothiazole, isoxazole, thiadiazole, oxadiazole, triazole, selenazole and tellurazole, preferably pyridine, pyrazine, pyrimidine and pyridazine, more preferably pyridine and pyrazine, and further preferably pyridine. The heterocyclic group formed with Q₃ may be further condensed with another ring and may have a substituent. Examples of the substituent include those exemplified as the substituent on the heterocyclic group represented by A in the general formula (IV), and preferred examples thereof are the same.

Specific examples of the compound represented by the general formula (IV) (including the compound represented by the general formula (VII) ) are shown below, but the invention is not limited thereto. Other examples thereof include the compounds disclosed in Japanese Patent Application No. 2004-082002 as Compound Nos. 1 to 20 in paragraphs 0086 to 0090 and Nos. 27 to 118 in paragraphs 0093 to 0121.

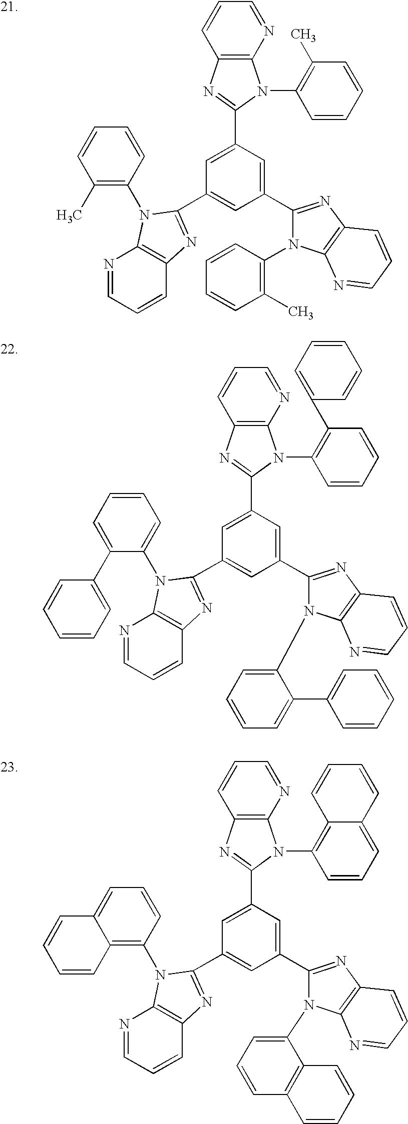

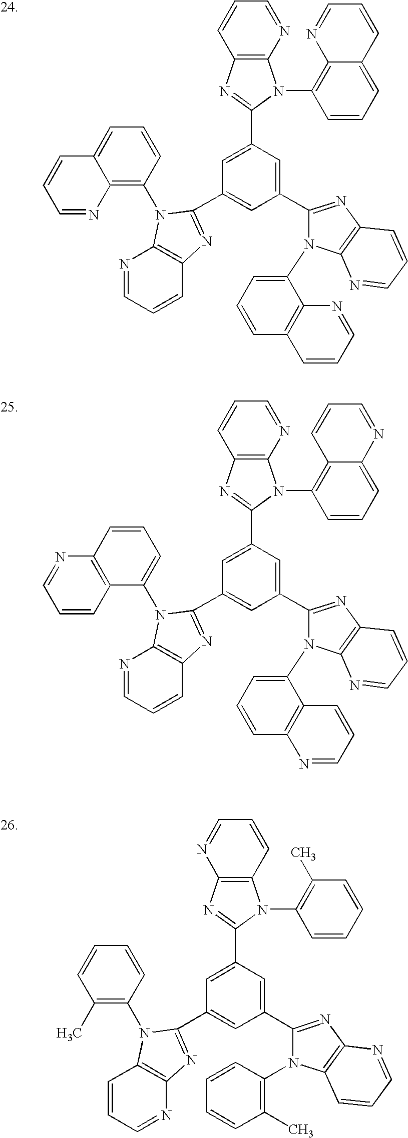

Detailed explanations and preferred ranges of the organic materials having an electron transporting nature are described in detail in Japanese Patent Application No. 2004-082002.

The metallic complex compound will be described below.

The metallic complex compound herein is such a metallic compound that has a ligand having at least one of a nitrogen atom, an oxygen atom and a sulfur atom coordinated to a metal. The metallic ion in the metallic complex is not particularly limited, and examples thereof include a beryllium ion, a magnesium ion, an aluminum ion, a gallium ion, a zinc ion, an indium ion and a tin ion, more preferably a beryllium ion, an aluminum ion, a gallium ion and a zinc ion, and further preferably an aluminum ion and a zinc ion.

There are various known ligands capable of being used as the ligand contained in the metallic complex, and examples of the ligand include those disclosed in H. Yersin, Photochemistry and Photophysics of Coordination Compounds, published by Springer-Varlag, Inc. (1987) and A. Yamamoto, Yuki Kinzoku Kagaku-Kiso to Oyo— (Organic Metallic Chemistry-Fundamentals and Applications-), published by Shokabo Co., Ltd. (1982)

The ligand is preferably a nitrogen-containing heterocyclic ligand (preferably having from 1 to 30 carbon atoms, more preferably having from 2 to 20 carbon atoms, and particularly preferably from 3 to 15 carbon atoms, which may be a unidentate ligand or a bidentate or higher dentate ligand, and preferably a bidentate ligand, such as a pyridine ligand, a bipyridyl ligand, a quinolinol ligand and a hydroxyphenylazole ligand (e.g., a hydoxyphenylbenzimidazole ligand, a hydroxyphenylbenzoxazole ligand and a hydroxyphenylimidazole ligand)), an alkoxy ligand (preferably having from 1 to 30 carbon atoms, more preferably from 1 to 20, and particularly preferably from 1 to 10, such as methoxy, ethoxy, butoxy and 2-ethylhexyloxy), an aryloxy ligand (preferably having from 6 to 30 carbon atoms, more preferably from 6 to 20 carbon atoms, and particularly preferably from 6 to 12 carbon atoms, such as phenyloxy, 1-naphthyloxy, 2-naphthyloxy, 2,4,6-trimethylphenyloxy and 4-biphenyloxy), an aromatic heterocyclic oxy ligand (preferably having from 1 to 30 carbon atoms, more preferably from 1 to 20 carbon atoms, and particularly preferably from 1 to 12 carbon atoms, such as pyridyloxy, prazyloxy, pyrimidyloxy and quinolyloxy), an alkylthio ligand (preferably having from 1 to 30 carbon atoms, more preferably from 1 to 20 carbon atoms, and particularly preferably from 1 to 12 carbon atoms, such as methylthio and ethylthio), an arylthio ligand (preferably having from 6 to 30 carbon atoms, more preferably from 6 to 20 carbon atoms, and particularly preferably from 6 to 12 carbon atoms), an aromatic heterocyclic thio ligand (preferably having from 1 to 30 carbon atoms, more preferably from 1 to 20 carbon atoms, and particularly preferably from 1 to 12 carbon atoms, such as pyridylthio, 2-benzimidazolylthio, 2-benzoxazolylthio and 2-benzthiazolylthio), a siloxy ligand (preferably having from 1 to 30 carbon atoms, more preferably from 3 to 25 carbon atoms, and particularly preferably from 6 to 20 carbon atoms, such as a triphenylsiloxy group, a triethoxysiloxy group and a triisopropylsiloxy group), more preferably a nitrogen-containing heterocyclic ligand, an aryloxy ligand, an aromatic heterocyclic oxy ligand and a siloxy ligand, and further preferably a nitrogen-containing heterocyclic ligand, an aryloxy ligand and a siloxy ligand.

The metallic complex contained in the charge transporting layer of the photoelectric conversion device of the invention is preferably a compound represented by the general formula (V), a compound represented by the general formula (VI), and a tautomer thereof, and more preferably a compound represented by the general formula (V) and a tautomer thereof. 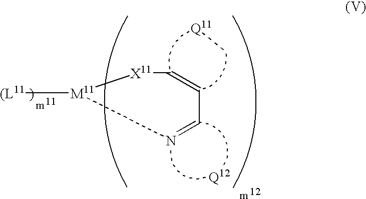
where in M¹¹ represents a metallic ion, L¹¹ represents a ligand, X¹¹ represents an oxygen atom, a substituted or unsubstituted nitrogen atom (examples of a substituent on the nitrogen atom include —SO₂R^{a}, —COR^{b} or —P(═O)(R^{c})(R^{d}), wherein R^{a}, R^{b}, R^{c} and R^{d} each represents an aliphatic hydrocarbon group, an aryl group, a heterocyclic group, an amino group, an alkoxy group, an aryloxy group or a heterocyclic oxy group) or a sulfur atom, Q¹¹ and Q¹² each represents an atomic group for forming an aromatic ring or an atomic group for forming a nitrogen-containing aromatic ring, provided that Q¹¹ and Q¹² may be bonded to form a condensed ring structure, and the rings formed by Q¹¹ and Q¹² each may have a substituent, and m¹¹ and m¹² each represents an integer of from 0 to 3 and an integer of from 1 to 4, respectively 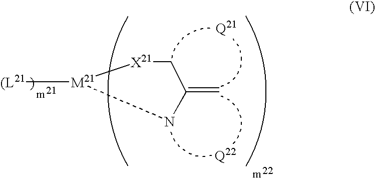
wherein L²¹ and X²¹ have the same meanings as L¹¹ and X¹¹, respectively, m¹¹ and m¹² each represents an integer of from 0 to 3 and an integer of from 1 to 4, respectively, M²¹ represents a metallic ion, and Q²¹ and Q²² each represents an atomic group for forming an aromatic ring or an atomic group for forming a nitrogen-containing aromatic ring, provided that Q²¹ and Q²² may be bonded to form a condensed ring structure, and the rings formed by Q¹¹ and Q¹² each may have a substituent.

The compounds represented by the general formulae (V) and (VI) are the same as the compounds represented by the general formulae (9) and (10) in JP-A-2002-338957, respectively, and tautomers thereof, and the specific examples and the synthesis methods therefor are also the same. The metallic complex used in the invention particularly preferably has a short wavelength end of film absorption spectrum at a wavelength shorter than Alq (aluminum quinoline).

The longer wavelength end of absorption of the charge transporting layer is preferably shorter than the longer wavelength end of absorption of the photoelectric conversion film, more preferably shorter by 50 nm or more, further preferably shorter by 100 nm or more, and particularly preferably shorter by 150 nm or more.

Furthermore, the longer wavelength end of absorption spectrum of the charge transporting layer is preferably 400 nm or less, more preferably 390 nm or less, and particularly preferably 380 nm or less.

The organic material having an electron transporting nature (n-type compound) in the photoelectric conversion film of the invention preferably has an ionization potential of 6.0 eV or more.

It has been found that in the case where the organic material having an electron transporting nature, the resulting photoelectric conversion film has a high photoelectric conversion efficiency and good durability.

From the standpoint of durability, such a device structure is preferred that a layer having a filter effect of absorbing light of 400 nm or less in the device to prevent the charge transporting layer from absorbing light, and it is further preferred that the longer wavelength end of absorption spectrum of the charge transporting layer is at a wavelength shorter than the shorter wavelength end of spectrum of the light thus irradiated.

[Wavelength Dependency of Absorption Strength]

It is preferred that the organic photoelectric conversion film has a film absorption spectrum in green light range in a wavelength range of 400 nm or more, and the absorption spectrum in the range has an absorption maximum having a maximum value of three times or more, preferably five times or more, and particularly preferably ten times or more, a maximum value of an absorption maximum in a wavelength range outside the range. The absorption spectrum preferably has a maximum value at a wavelength of from 500 to 600nm, more preferably from 520to580 nm, and particularly preferably from 530 to 570 nm.

[Spectral Sensitivity]

The photoelectric conversion spectrum, which indicates the spectral sensitivity, preferably has a maximum value at a wavelength of from 510 to 570 nm, and more preferably from 520to560nm. By using the device of the invention satisfying the requirements, a BGR photoelectric conversion film, i.e., a laminated photoelectric conversion film having three layers including a blue photoelectric conversion film, a green photoelectric conversion film and a red photoelectric conversion film, with good color reproducibility can be preferably used to realize good color reproducibility.

[Ionization Potential (Ip) and Electron Affinity (Ea)]

It has found that the efficiency can be improved in the case where the ionization potential (Ip) and the electron affinity (Ea) of the photoelectric conversion film of the photoelectric conversion device having the BGR spectral capability satisfy the following conditions.

That is, the ionization potential (Ip₁) and the electron affinity (Ea₁) of the positive hole transporting photoelectric conversion film and the ionization potential (IP₂) and the electron affinity (Ea₂) of the electron transporting photoelectric conversion film preferably satisfy relationships Ip₁<IP₂ and Ea₁<Ea₂.

The charge transporting layer is formed by a dry film forming method or a wet film forming method. Specific examples of the dry film forming method include a physical vapor phase growing method, such as a vacuum deposition method, an ion plating method and MBE method, and a CVD method, such as a plasma polymerization method. Examples of the wet film forming method include a casting method, a spin coating method, a dipping method and an LB method. The forming method of the charge transporting layer is preferably a dry method, and particularly preferably a vacuum deposition method.

[Electrode]

A positive electrode is defined as such an electrode that takes out positive holes from the positive hole transporting photoelectric conversion layer or the positive hole transporting layer, and can be formed with a metal, an alloy, a metallic oxide, an electroconductive compound, or a mixture thereof, and preferably with a material having a work function of 4 eV or more. Specific examples thereof include an electroconductive metallic oxide, such as tin oxide, zinc oxide, indium oxide and indium tin oxide (ITO), a metal, such as gold, silver, chromium and nickel, a mixture or a laminated material of a metal and an electroconductive metallic oxide, an inorganic electroconductive substance, such as copper iodide and copper sulfide, an organic electroconductive material, such as polyaniline, polythiophene and polypyrrole, a silicone compound, and a laminated body of these materials with ITO, and preferably an electroconductive metallic oxide, and in particular, ITO is preferred from the standpoint productivity, high electroconductivity and transparency. The thickness of the positive electrode can be appropriately selected depending on the material, and in general, it is preferably from 10 nm to 5 μm, more preferably from 50 nm to 1 μm, and further preferably from 100 to 500 nm.

The positive electrode is generally formed as a layer on such a substrate as soda lime glass, non-alkali glass and a transparent resin substrate. In the case where glass is used, non-alkali glass is preferably used in order to suppress ions from being eluted from the glass. In the case where soda lime glass is used, it is preferred that a barrier coating, such as silica, is formed thereon. The thickness of the substrate is not particularly limited as far as it has sufficient mechanical strength, and in the case where glass is used, the thickness is generally 0.2 mm or more, and preferably 0.7 mm or more. The production method of the positive electrode may be variously selected depending on the material therefor, and in the case of ITO for example, the layer can be formed by an electron beam method, a sputtering method, a resistance heating vapor deposition method, a chemical reaction method (such as a sol-gel method), and a method of coating a dispersion of indium tin oxide. The positive electrode can be improved in luminescent efficiency through reduction of the driving voltage of the device by cleaning the positive electrode. In the case of ITO, for example, the positive electrode can be effectively cleaned by an UV-ozone treatment or a plasma treatment.

A negative electrode is to take out electrons from the electron transporting photoelectric conversion layer or the electron transporting layer, and the material therefor is selected in consideration of adhesion to the adjacent layer, such as the electron transporting photoelectric conversion layer and the electron transporting layer, the electron affinity, the ionization potential, and the stability. Examples of the material for the negative electrode include a metal, an alloy, a metallic halide, a metallic oxide, an electroconductive compound, ITO, IZO, and a mixture thereof, and specific examples thereof include an alkali metal (e.g., Li, Na and K) and a fluoride or an oxide thereof, an alkaline earth metal (e.g., Mg and Ca) and a fluoride or an oxide thereof, gold, silver, lead, aluminum, a sodium-potassium alloy or a mixed metal thereof, a lithium-aluminum alloy or a mixed metal thereof, a magnesium-silver alloy or a mixed metal thereof, and a rare earth metal, such as indium and ytterbium, preferably a material having a work function of 4 eV or less, and more preferably aluminum, silver, gold and a mixed metal thereof. The negative electrode may have a laminated structure of the aforementioned compounds and mixtures, as well as a single layer structure of the aforementioned compound or mixture. Examples of the laminated structure include laminated structures of aluminum and lithium fluoride, and aluminum and lithium oxide. The thickness of the negative electrode can be appropriately selected depending on the material, and in general, it is preferably from 10 nm to 5 μm, more preferably from 50 nm to 1 μm, and further preferably from 100 nm to 1 μm.

The negative electrode can be produced by an electron beam method, a sputtering method, a resistance heating vapor deposition method and a coating method, and a single component of a metal can be solely vapor-deposited, or plural components can be simultaneously vapor-deposited. Furthermore, plural metals can be simultaneously vapor-deposited to form an alloy electrode, and an alloy having been prepared may be vapor-deposited. The sheet resistance of the positive electrode and the negative electrode is preferably as low as possible, specifically it is preferably several hundreds Ω per square.

[Generic Requirements]

It is preferred in the invention that the photoelectric conversion device has two or more layers of the photoelectric conversion film laminated, more preferably three or four layers thereof laminated, and particularly preferably three layers thereof laminated.

In the invention, the photoelectric conversion device can be preferably used as an imaging device.

In the invention, the photoelectric conversion film, the photoelectric conversion device and the imaging device are preferably applied with a voltage.

It is preferred in the photoelectric conversion device of the invention that a p-type semiconductor layer and an n-type semiconductor layer form a laminated structure between a pair of electrodes. It is more preferred that at least one of the p-type and n-type semiconductor layers contain an organic compound, and it is further preferred that both the p-type and the n-type semiconductor layers contain an organic compound.

[Application of Voltage]

It is preferred that the photoelectric conversion film of the invention is applied with a voltage since the photoelectric conversion efficiency is improved. The voltage applied is not particularly limited, and the necessary voltage varies depending on the thickness of the photoelectric conversion film. That is, the photoelectric conversion efficiency is improved when the electric field applied is increased, and the electric field is increased by decreasing the thickness of the photoelectric conversion film with the constant applied voltage. Therefore, the applied voltage may be relatively small when the thickness of the photoelectric conversion film is small. The electric field applied to the photoelectric conversion film is preferably 10 V/m or more, more preferably 10×10³ V/m or more, more preferably 1×10⁵ V/m or more, particularly preferably 1×10⁶ V/m or more, and most preferably 1×10⁷ V/m or more. The upper limit of the electric field is not particularly limited, and is preferably 1×10¹² V/m or less, and more preferably 1×10⁹ V/m or less, since an electric current flows in a dark space when the electric field is too large.

[Bulk Hetero Junction Structure]

In the invention, the photoelectric conversion film (photosensitive layer) preferably has such a structure that the p-type semiconductor layer and the n-type semiconductor layer intervene between a pair of electrodes, wherein at least one of the semiconductor layers contain an organic semiconductor, and a bulk hetero junction structure layer containing the p-type semiconductor and the n-type semiconductor intervenes between the semiconductor layers. In the case where the photoelectric conversion film has the structure, the organic layer has the bulk hetero junction structure, whereby such a disadvantage that the carrier diffusion length of the organic layer is short can be avoided to improve the photoelectric conversion efficiency.

The bulk hetero junction structure is described in detail in Japanese Patent Application No. 2004-080639.

[Tandem Structure]

In the invention, the photoelectric conversion film (photosensitive layer) preferably has such a structure that two or more repeated structures (tandem structures) of a pn-junction layer formed by the p-type semiconductor layer and the n-type semiconductor layer intervening between a pair of electrodes, and more preferably such a structure that a thin layer of an electroconductive material intervenes between the repeated structures. The number of the repeated structures (tandem structures) of the pn-junction layer is not limited, and is preferably from 2 to 50, more preferably from 2 to 30, and particularly preferably from 2 to 10, for improving the photoelectric conversion efficiency. The electroconductive material is preferably silver or gold, and most preferably silver.

In the invention, the semiconductor having the tandem structure may be an inorganic material, but is preferably an organic semiconductor, and more preferably an organic colorant.

The tandem structure is described in detail in Japanese Patent Application No. 2004-079930.

[Orientation]

In the case where the imaging device of the invention has a photoelectric conversion film having a p-type semiconductor layer and an n-type semiconductor layer (preferably a mixed and dispersed layer (having the bulk hetero structure)), the photoelectric conversion film preferably has such a structure that at least one of the n-type semiconductor and the n-type semiconductor contains an organic compound having been controlled in orientation in one direction, and more preferably both the n-type semiconductor and the n-type semiconductor contain an organic compound having been oriented (or an organic compound capable of being oriented).

The organic compound used in the organic layer of the photoelectric conversion film preferably has π-conjugated electrons, and it is preferred that the π-electron plane is not perpendicular to the substrate (electrode substrate) but is oriented in such a direction that is as close as possible to the angle in parallel to the substrate. The angle of the n-electron plane to the substrate is preferably from 0 to 80°, more preferably from 0 to 60°, further preferably from 0 to 40°, still further preferably from 0 to 20°, particularly preferably from 0 to 10°, and most preferably 0° (i.e., in parallel to the substrate).

The layer of an organic compound having been controlled in orientation may be contained as at least a part of the whole organic layer, and is preferably contained in a proportion of 10% or more, more preferably 30% or more, further preferably 50% or more, still further preferably 70% or more, particularlypreferably 90% ormore, andmost preferably 100%, of the whole organic layer.

According to the constitution, the organic compound in the organic layer of the photoelectric conversion film is controlled in orientation, whereby such a disadvantage that the carrier diffusion length of the organic layer is short can be avoided to improve the photoelectric conversion efficiency.

In the case where the organic compound in the invention has been controlled in orientation, it is more preferred that the hetero junction plane (for example, the pn-junction plane) is not in parallel to the substrate. It is preferred that the hetero junction plane is not in parallel to the substrate (electrode substrate) but is oriented in such a direction that is as close as possible to the angle perpendicular to the substrate. The angle of the hetero junction plane to the substrate is preferably from 10 to 90°, more preferably from 30 to 90°, further preferably from 50 to 90°, still further preferably from 70 to 90°, particularly preferably from 80 to 90°, and most preferably 90° (i.e., perpendicular to the substrate).

The layer of an organic compound having been controlled in hetero junction plane may be contained as at least a part of the whole organic layer, and is preferably contained in a proportion of 10% or more, more preferably 30% or more, further preferably 50% or more, still further preferably 70% or more, particularly preferably 90% or more, and most preferably 100%, of the whole organic layer. According to the constitution, the area of the hetero junction plane in the organic layer is increased, whereby the amount of carriers, such as electrons, positive holes and electron-positive hole pairs, is increased to improve the photoelectric conversion efficiency.

The photoelectric conversion film having been controlled in orientation of both the hetero junction plane and the π-electron plane can provide a particularly improved photoelectric conversion efficiency.

The aforementioned constitutions are described in detail in Japanese Patent Application No. 2004-079931.

[Thickness of Organic Colorant Layer]

In the case where the photoelectric conversion film of the invention is used as a color imaging device (image sensor), the B, G and R layers of the organic colorant layers preferably have a light-absorbing ratio of 50% or more, more preferably 70% or more, particularly preferably 90% (absorbance of 1) or more, and most preferably 99% or more, for improving the photoelectric conversion efficiency and for improving the color separation without irradiating the lower layer with unnecessary light. Therefore, the thickness of the organic colorant layer is preferably as large as possible from the standpoint of light absorption, but in consideration of such a proportion that does not contribute to charge separation, the thickness of the organic colorant layer in the invention is preferably from 30 to 300 nm, more preferably from 50 to 150 nm, and particularly preferably from 80 to 130 nm.

[BGR Spectral Capability]

In the invention, a BGR photoelectric conversion film, i.e., a laminated photoelectric conversion film having three layers including a blue photoelectric conversion film, a green photoelectric conversion film and a red photoelectric conversion film, with good color reproducibility can be preferably used.

The respective photoelectric conversion films preferably have the aforementioned spectral absorption and/or spectral sensitivity characteristics.

[Laminated Structure]

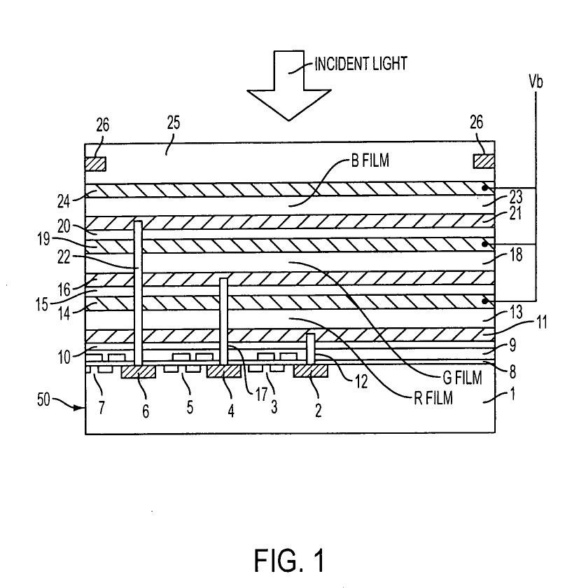

It is preferred in the invention that the photoelectric conversion device has at least two photoelectric conversion films laminated to each other. The laminated imaging device is not particularly limited, and any type thereof used in this field of art can be applied. It is preferred that the imaging device has a BGR three-layer laminated structure, and a preferred example of the BGR three-layer laminated structure is shown in FIG. 1.

The solid imaging device according to the invention has, for example, a photoelectric conversion film according to this embodiment. The solid imaging device shown in FIG. 1 has a laminated photoelectric conversion film on a scanning circuit. The scanning circuit may have such a structure that MOS transistors for each pixel are formed on a semiconductor substrate, or such a structure that has a CCD as an imaging device.

In the case of the solid imaging device using MOS transistors, charge is formed in the photoelectric conversion film by incident light passing through the electrode, and the charge moves within the photoelectric conversion film to the electrode through an electric field between the electrodes generated by applying a voltage to the electrodes and further moves to the charge accumulating part of the MOS transistor, whereby the charge is accumulated in the charge accumulating part. The charge thus accumulated in the charge accumulating part moves to the charge read-out part through switching of the MOS transistor, and is output as an electric signal. Accordingly, a full color image signal is input to the solid imaging device including a signal processing part.

As the laminated imaging device, a solid color imaging device, which is represented by those disclosed in FIG. 2 of JP-A-58-103165 and FIG. 2 of JP-A-58-103166, can be applied.

As the production process of the laminated imaging device, preferably the three-layer laminated imaging device, the process disclosed in JP-A-2002-83946, FIGS. 7 to 23 and paragraphs 0026 to 0038.

The device of the invention may have such a structure that has a first light receiving part detecting light of a first wavelength range, a second light receiving part detecting light of a second wavelength range, and a third light receiving part detecting light of a third wavelength range, in which the first light receiving part is an organic photoelectric conversion film formed of a positive hole transporting material containing the quinacridone derivative represented by the general formula (I) or the quinazoline derivative represented by the general formula (II), and an electron transporting material having a maximum wavelength at a wavelength shorter than the maximum wavelength of the absorption spectrum of the positive hole transporting material, and the second and third light receiving parts are formed in the silicon substrate.

### EXAMPLE

The invention will be described in more detail with reference to the following examples, but the invention is not limited thereto.

### Example 1

Production of Device No. 101

A cleaned ITO substrate was placed in a vapor deposition apparatus, on which a benzylidene compound (D-2) of the invention was vapor-deposited to 100 nm, and Alq (aluminum quinoline) was further vapor-deposited to 500 nm, so as to form an organic pn-laminated photoelectric conversion layer. A patterned mask (having a luminescent area of 2 mm×2 mm) was placed on the organic thin film, on which aluminum was vapor-deposited to 500 nm in a vapor deposition apparatus. The assembly was then sealed with a desiccant to produce a photoelectric conversion device for green light (Device No. 101).

Production of Device No. 102

The same procedures as the Device No. 101 in Example 1 were repeated except that after vapor-depositing the compound (D-2), BAlq was further vapor-deposited thereon to 50 nm, and further the electron transporting material No. 24 was vapor-deposited to 70 nm. The assembly was sealed with an aluminum electrode in the same manner as in Example 1 to produce a photoelectric conversion device (Device No. 102).

Production of Device No. 103

The same procedures as the Device No. 101 in Example 1 were repeated except that after vapor-depositing the compound (D-2) to 100 nm, the electron transporting material No.24 was vapor-deposited to 100 nm. The assembly was sealed with an aluminum electrode in the same manner as in Example 1 to produce a photoelectric conversion device (Device No. 103).

Production of Device Nos. 104 and 105

The same procedures as the Device No. 103 were repeated except that the compound (D-2) was changed to the compounds (D-17) and (D-64), respectively, to produce photoelectric conversion devices (Device Nos. 104 and 105).

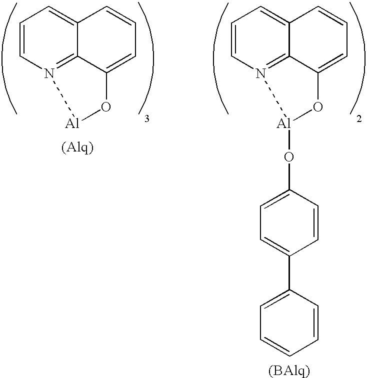

The devices were evaluated in the following manner.

The wavelength dependency of external quantum efficiency (IPCE) was evaluated by using a solar cell evaluation apparatus, produced by Optel Co., Ltd. The resulting photoelectric conversion spectrum was subjected to simulation to evaluate spectral characteristics as a BGR device, and the color reproducibility (spectral characteristics) was evaluated by three grades, A, B and C. The durability was evaluated in such a manner that the device was continuously irradiated with light with AM0 spectrum of 1.5 G and 100 mW/m² for 24 hours by using a solar simulator, and the extent of reduction in external quantum efficiency was evaluated by three grades, A, B and C. The results obtained are shown in Table 1 below.

TABLE 1

| | | | Electron | External | | |
|---|---|---|---|---|---|---|
| | p-type | n-type | transporting | quantum | Spectral | |
| Device No. | compound | compound | material | efficiency | characteristics | Durability |
| 101 | D-2 | Alq | none | 8% | B | A |
| 102 | D-2 | BAlq | 24 | 10% | A-B | A |
| 103 | D-2 | none | 24 | 11% | A | A |
| 104 | D-17 | none | 24 | 9% | A | A |
| 105 | D-64 | none | 24 | 10% | A | A |

The devices of the invention had spectral sensitivity in a green range and had a distinctly high efficiency in comparison to the device having a photoelectric conversion film of rhodamine 6G and polysilane having photosensitivity in a green region disclosed in the example of JP-A-2003-234460 (efficiency: 1%). Furthermore, the devices using the electron transporting material No. 24 had no sensitivity near 400 nm to provide excellent spectral characteristics. The devices of the invention had good durability.

A three-layer laminated imaging device as shown in FIG. 1 can be produced in such a manner that a device having blue spectral sensitivity is produced in the same manner, which is combined with a red-sensitive device and a green-sensitive device.

The photoelectric conversion film, the photoelectric conversion device and the imaging device of the invention have a narrow half value width of absorption to provide excellent color reproducibility, and have high photoelectric conversion efficiency and excellent durability. The BGR three-layer laminated solid imaging device according to the invention further has the following advantages in addition to the aforementioned ones.

Owing to the three-layer structure, it is free of moire, has high resolution without necessity of an optical low-pass filter, is free of color blur, and is free of quasi-signal with simple signal processing. In the case of CMOS devices, image mixture is facilitated, and partial read-out is also facilitated.

Owing to an aperture ratio of 100% and unnecessity of microlens, it has no limitation in exit pupil distance to an imaging lens with no shading. Therefore, it is suitable for a lens-exchangeable camera, and a lens therefor can be reduced in profile.

Owing to unnecessity of microlens, it can be sealed with glass by charging an adhesive, and thus a package thereof can be reduced in profile and improved in yield to reduce costs.

Owing to the use of an organic colorant, it has high sensitivity without an IR filter to reduce flare.

The entire disclosure of each and every foreign patent application from which the benefit of foreign priority has been claimed in the present application is incorporated herein by reference, as if fully set forth.

What is claimed is:

1. A photoelectric conversion device comprising:
at least two electrodes; and
an organic photoelectric conversion film intervening between said at least two electrodes, the organic photoelectric conversion film comprising a positive hole transporting material containing an arylidene compound represented by the following general formula (I) 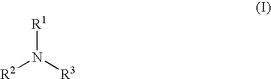
wherein R¹, R² and R³ each independently represents an aryl group, a heterocyclic group or an alkyl group, provided that at least one of R¹, R² and R³ represents an aryl group or a heterocyclic group, at least one of an aryl group and a heterocyclic group represented by R¹, R² and R³ has a substituent containing a group represented by the following general formula (II), and two or more of R¹, R² and R³ may be connected to form a ring 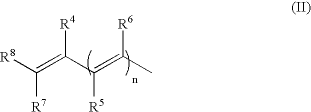
wherein R⁴, R⁵ and R⁶ each independently represents a hydrogen atom or a substituent; R⁷ and R⁸ each independently represents a hydrogen atom or a substituent, at least one of which represents an electron withdrawing group; and n represents 0, 1 or 2.

2. The photoelectric conversion device as claimed in claim 1, wherein the group represented by the general formula (II) as a substituent in the general formula (I) is a group represented by the following general formula (III) 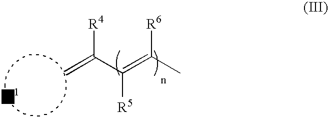
wherein R⁴, R⁵, R⁶ and n have the same meanings as in the general formula (II), and Z¹ represents an atomic group forming a 5- to 7-membered ring.

3. The photoelectric conversion device as claimed in claim 1, wherein the organic photoelectric conversion film further comprises an electron transporting material having a maximum wavelength of an absorption spectrum at a maximum wavelength or lower of an absorption spectrum of the positive hole transporting material.

4. The photoelectric conversion device as claimed in claim 3, wherein the electron transporting material is: a 5- to 7-membered heterocyclic compound having a nitrogen atom, an oxygen atom or a sulfur atom; a condensed aromatic carbocyclic compound; or a metallic complex having a nitrogen-containing heterocyclic compound as a ligand.

5. The photoelectric conversion device as claimed in claim 1, wherein the organic photoelectric conversion film has a film absorption spectrum that has a maximum on the longest wavelength side, the film absorption spectrum having a half value width of from 50 to 150 nm.

6. The photoelectric conversion device as claimed in claim 1, further comprising at least one charge transporting layer transporting electrons formed through photoelectric conversion, wherein the charge transporting layer has an absorption spectrum having a longer wavelength end at a wavelength shorter than a longer wavelength end of aluminum quinoline (Alq).

7. The photoelectric conversion device as claimed in claim 1, further comprising at least one charge transporting layer transporting electrons formed through photoelectric conversion, wherein the charge transporting layer has an absorption spectrum having a longer wavelength end at a wavelength of 400 nm or less.

8. The photoelectric conversion device as claimed in claim 1, wherein the photoelectric conversion device further comprises at least one charge transporting layer transporting positive holes or electrons formed through photoelectric conversion, and a filter layer absorbing light having a wavelength of 400 nm or less, and has such a structure that the charge transporting layer does not absorb light owing to light absorption by the filter layer.

9. The photoelectric conversion device as claimed in claim 1, wherein the organic photoelectric conversion film has an absorption spectrum having a maximum value at a wavelength of from 510 to 570 nm.

10. The photoelectric conversion device as claimed in claim 3, wherein the electron transporting material is a compound represented by the following general formula (IV) 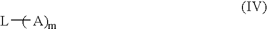
wherein A represents a heterocyclic ring containing two or more aromatic heterocyclic rings condensed to each other, provided that plural heterocyclic rings represented by A are the same as or different from each other; m represents an integer of 2 or more; and L represents a linking group.

11. The photoelectric conversion device as claimed in claim 6, wherein the charge transporting layer comprises a compound represented by the following general formula (IV) 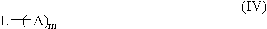
wherein A represents a heterocyclic ring containing two or more aromatic heterocyclic rings condensed to each other, provided that plural heterocyclic rings represented by A are the same as or different from each other; m represents an integer of 2 or more; and L represents a linking group.

12. The photoelectric conversion device as claimed in claim 7, wherein the charge transporting layer comprises a compound represented by the following general formula (IV) 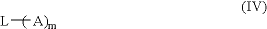
wherein A represents a heterocyclic ring containing two or more aromatic heterocyclic rings condensed to each other, provided that plural heterocyclic rings represented by A are the same as or different from each other; m represents an integer of 2 or more; and L represents a linking group.

13. The photoelectric conversion device as claimed in claim 8, wherein the charge transporting layer comprises a compound represented by the following general formula (IV) 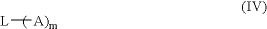
wherein A represents a heterocyclic ring containing two or more aromatic heterocyclic rings, condensed to each other, provided that plural heterocyclic rings represented by A are the same as or different from each other; m represents an integer of 2 or more; and L represents a linking group.

14. The photoelectric conversion device as claimed in claim 10, wherein the compound represented by the general formula (IV) is a compound represented by the following general formula (VII) 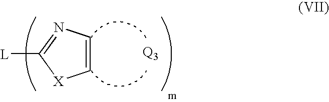
wherein X represents O, S, Se, Te or N—R; R represents a hydrogen atom, an aliphatic hydrocarbon group, an aryl group or a heterocyclic group; Q₃ represents an atomic group forming an aromatic heterocyclic ring; m represents an integer of 2 or more; and L represents a linking group.

15. The photoelectric conversion device as claimed in claim 11, wherein the compound represented by the general formula (IV) is a compound represented by the following general formula (VII) 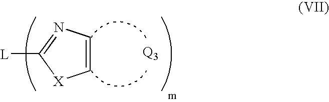
wherein X represents O, S, Se, Te or N—R; R represents a hydrogen atom, an aliphatic hydrocarbon group, an aryl group or a heterocyclic group; Q₃ represents an atomic group forming an aromatic heterocyclic ring; m represents an integer of 2 or more; and L represents a linking group.

16. The photoelectric conversion device as claimed in claim 12, wherein the compound represented by the general formula (IV) is a compound represented by the following general formula (VII) 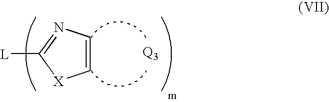
wherein X represents O, S, Se, Te or N—R; R represents a hydrogen atom, an aliphatic hydrocarbon group, an aryl group or a heterocyclic group; Q₃ represents an atomic group forming an aromatic heterocyclic ring; m represents an integer of 2 or more; and L represents a linking group.

17. The photoelectric conversion device as claimed in claim 13, wherein the compound represented by the general formula (IV) is a compound represented by the following general formula (VII) 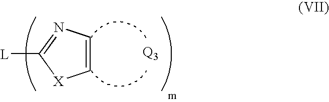
wherein X represents O, S, Se, Te or N—R; R represents a hydrogen atom, an aliphatic hydrocarbon group, an aryl group or a heterocyclic group; Q₃ represents an atomic group forming an aromatic heterocyclic ring; m represents an integer of 2 or more; and L represents a linking group.

18. An imaging device comprising the photoelectric conversion device as claimed in claim 1.

19. An imaging device comprising:
a first light receiving part detecting light in a first wavelength range;
a second light receiving part detecting light in a second wavelength range; and
a third light receiving part detecting light in a third wavelength range,
wherein the first light receiving part comprises a photoelectric conversion device as claimed in claim 1, and the second and third light receiving parts each comprises a light receiving part formed in a silicon substrate.
